(19) United States
(12) Patent Application Publication
(10) Pub. No.: US 2022/0263040 A1
(43) Pub. Date: Aug. 18, 2022

(54) COMBINED CHARGE TRANSPORTING AND EMITTING LAYER WITH IMPROVED MORPHOLOGY AND BALANCED CHARGE TRANSPORTING PROPERTIES

(71) Applicant: SHARP KABUSHIKI KAISHA, Sakai City (JP)

(72) Inventor: ENRICO ANGIONI, Oxford (GB)

(21) Appl. No.: 17/177,931

(22) Filed: Feb. 17, 2021

(51) Int. Cl. H01L 51/50; H01L 51/00; H01L 51/56

(52) U.S. Cl. CPC H01L 51/502; H01L 51/5056; H01L 51/5072; H01L 51/5088; H01L 2251/552; H01L 51/0003; H01L 51/0026; H01L 51/56; H01L 51/5092

(57) ABSTRACT

A light-emitting structure includes an anode, a cathode, a combined charge transport and emissive layer disposed between the anode and the cathode, and an interlayer of a material with at least electron blocking properties. The interlayer is disposed adjacent an upper outer surface of the combined charge transport and emissive layer. The combined charge transport and emissive layer comprises quantum dots (QDs) with ligands, and the QDs are dispersed in a crosslinked matrix formed at least partially from at least one crosslinkable charge transport material other than the ligands.

### FIELD

The present disclosure is related to a layer structure used for an emissive apparatus, such as a quantum dot light-emitting diode (QLED). In particular, the present disclosure seeks to describe a QLED structure for patterned apparatuses with improved morphology of the emissive—charge transporting interface and improved charge balance.

### BACKGROUND

A common architecture for a light-emitting apparatus includes an anode, which acts as hole injector; a hole transport layer disposed on the anode; an emissive material layer disposed on the hole transport layer; an electron transport layer disposed on the emissive material layer; and a cathode, which also acts as an electron injector, disposed on the electron transport layer. When a forward bias is applied between the anode and cathode, holes and electrons are transported in the apparatus through the hole transport layer and electron transport layer, respectively. The holes and electrons recombine in the emissive material layer, which generates light that is emitted from the apparatus. When the emissive material layer includes an organic material, the light-emitting apparatus is referred to as an organic light-emitting diode (OLED). When the emissive material layer includes nanoparticles, sometimes known as quantum dots (QDs), the apparatus is commonly referred to as either a quantum dot light-emitting diode (QLED, QD-LED) or an electroluminescent quantum dot light-emitting diode (ELQLED, QDEL).

These layers are deposited on a substrate and it is possible to have different structures based on the order of deposition of the layers. In a standard structure the first layer deposited on the substrate is the anode, followed by the hole transporting layer, the emissive layer, the electron transporting layer and finally by the cathode. In an inverted structure, these layers are deposited on the substrate on the opposite order, starting with the cathode and finishing with the anode.

Each of the layers of the light-emitting apparatus can be deposited by different methods with the common methods including thermal evaporation methods and solution process methods. Thermal evaporation methods are widely used for OLEDs, but they are more complex and have higher costs of fabrication as compared to solution process methods. Solution process methods are thus preferred as a cheaper and simpler fabrication methods. However, in the fabrication of apparatuses with these methods, it is important to find the appropriate solvents such that during the deposition of a particular layer, the process will not dissolve or otherwise damage the previously deposited layer. Such a non-damaging solvent is typically referred to in the art as “orthogonal” to the previous one (See, http://dx.doi.org/10.1016/j.orgel.2015.12.008; Gaiwad, Abhinay M., et al. “Identifying orthogonal solvents for solution processed organic transistors” Organic Electronics, 2016).

To include QLEDs in multicolor high resolution displays, different manufacturing methods have been designed. These methods typically include depositing three different types of QDs on three different regions of a substrate such that each region emits light (through electrical injection; i.e. by electroluminescence) at three different colors, particularly red (R), green (G) and blue (B). Sub-pixels that respectively emit red, green, or blue light may collectively form a pixel, which in turn may be a part of an array of pixels of the display.

Angioni et al. (U.S. Pat. No. 10,581,007) discusses a structure for patterned QLEDs. The structure involves an anode, a cathode and an emissive layer disposed between the anode and the cathode, the emissive layer comprising quantum dots comprising ligands, the quantum dots dispersed in a crosslinked matrix formed at least partially from one or more crosslinkable charge transport materials other than the ligands. This layer forms a combined charge transporting and emitting layer that can be patterned in specific areas of a substrate. This disclosure can be used to create multicolor high resolution displays, patterning QLED structures with three different colors, particularly red (R), green (G) and blue (B).

In this structure, the morphology of the resulting layer is not ideal, with concave and convex areas due to the intrinsic properties of the QDs. In fact, having high surface area, they tend to minimize they surface free energy phase separating on the upper outer surface of the layer and self-assembling into hexagonal close-packed (hcp) arrays as they seek their equilibrium conformation, coarsening via a combination of Ostwald ripening and cluster diffusion, depending on the stage of coarsening and the initial QD concentration (DOI: 10.1002/adfm.200400468; Coe-Sullivan et al., Large—Area Ordered Quantum—Dot Monolayers via Phase Separation During Spin—Casting, Adv. Funct. Mater. 2005, 15, 1117-1124).

It is known that the hole mobility is usually lower than that of electron in QLEDs (DOI:10.1038/nature13829, Dai et al., Solution-processed, high-performance light-emitting diodes based on quantum dots, Nature, 2014, 515, 96-99).

Recent studies in OLEDs (DOI: 10.1002/adfm.201901025; Tsai et al., Solution—Processed Thermally Activated Delayed Fluorescent OLED with High EQE as 31% Using High Triplet Energy Crosslinkable Hole Transport Materials. Adv. Funct. Mater., 2019, 29, 1901025) and QLEDs (DOI: 10.1002/adma.201801387; Zhang et al., High-Performance, Solution-Processed, and Insulating-Layer-Free Light-Emitting Diodes Based on Colloidal Quantum Dots, Adv. Mater. 2018, 30, 1801387) have indicated that double or blended HTL structures with a stepwise HOMO energy level alignment could benefit the hole transport at interfaces in order to balance this.

Tang et al. (DOI: 10.1021/acsami.0c01001; Realizing 22.3% EQE and 7-Fold Lifetime Enhancement in QLED: via Blending Polymer TFB and Cross-linkable Small Molecule for Solvent-Resistant Hole Transport Layer) take a step further. In this related art TFB and crosslinkable small molecules are mixed and deposited together in order to create a HTL with improved hole transporting properties and solvent resistance.

Other approaches consist in the inclusion of thin layers of an insulating material within the QDs emissive layer in a layer by layer multilayer structure (DOI: 10.1002/adfm.201906742; Rahmati et al., Highly Efficient Quantum Dot Light-Emitting Diodes by Inserting Multiple Poly(methyl methacrylate) as Electron-Blocking Layers Adv. Funct. Mater. 2019, 1906742) or the inclusion of a thin layer of an insulating material between the QDs emissive layer and the electron transporting layer (Dai et al., Id.).

### CITATION LIST

Gaiwad, Abhinay M., et al. “Identifying orthogonal solvents for solution processed organic transistors,” Organic Electronics, vol. 30, 2016, pp. 18-29 (https://doi.org/10.1016/j.orgel.2015.12.008).

Angioni et al., “Crosslinked emissive layer containing quantum dots for light-emitting device and method for making same,” U.S. Pat. No. 10,581,007 (2020).

Coe-Sullivan, S., et al., “Large-Area Ordered Quantum-Dot Monolayers via Phase Separation During Spin-Casting,” Adv. Funct. Mater., vol. 15, no. 7, 2005, pp. 1117-1124 (https://doi.org/10.1002/adfm.200400468).

Dai, Xingliang, et al., “Solution-processed, high-performance light-emitting diodes based on quantum dots,” Nature, vol. 515, 2014, pp. 96-99 (https://doi.org/10.1038/nature13829).

Tsai, Kuen-Wei, et al., “Solution-Processed Thermally Activated Delayed Fluorescent OLED with High EQE as 31% Using High Triplet Energy Crosslinkable Hole Transport Materials,” Adv. Funct. Mater., vol. 29, no. 15, 2019, 1901025 (https://doi.org/10.1002/adfm.201901025).

Zhang, Zhenxing, et al., “High-Performance, Solution-Processed, and Insulating-Layer-Free Light-Emitting Diodes Based on Colloidal Quantum Dots,” Adv. Mater., vol. 30, no. 28, 2018, 1801387 (https://doi.org/10.1002/adma.201801387).

Tang, Pengyu, et al., “Realizing 22.3% EQE and 7-Fold Lifetime Enhancement in QLED: via Blending Polymer TFB and Cross-linkable Small Molecule for Solvent-Resistant Hole Transport Layer,” ACS Appl. Mater. Interfaces, vol. 12, no. 11, 2020, pp. 13087-13095 (https://doi.org/10.1021/acsami.0c01001).

Rahmati, Mohammad, et al., “Highly Efficient Quantum Dot Light-Emitting Diodes by Inserting Multiple Poly(methyl methacrylate) as Electron-Blocking Layers,” Adv. Funct. Mater., vol. 29, no. 50, 2019, 1906742 (https://doi.org/10.1002/adfm.201906742).

### SUMMARY

A light-emitting apparatus is disclosed, the light-emitting apparatus having an anode, a cathode, and a combined charge transport and emissive layer disposed between the anode and the cathode. An interlayer of material with at least electron blocking properties, is disposed adjacent an upper outer surface of the combined charge transport and emissive layer. The combined charge transport and emissive layer comprises quantum dots (QDs) with ligands, and the QDs are dispersed in a crosslinked matrix formed at least partially from at least one crosslinkable charge transport material other than the ligands.

The combined charge transport and emissive layer is preferably arranged such that the interlayer is formed by a crosslinked, crosslinkable material with one or more functional groups. The one or more functional groups may comprise an epoxide, an oxetane, an alkane, an alkene, an alkyne, a thiol, an aldehyde, a ketone, a carboxyl, a methacrylate, an acrylate or an azide.

Ligands may have at least one functional group needed to bind to the QDs, this can be: a thiol, an amine, a carboxylic acid, a phosphine, and the like. In this invention the ligands may have then a second functional group needed to crosslink, this can be: an epoxide, an oxetane, an alkane, an alkene, an alkyne, a thiol, an aldehyde, a ketone, a carboxyl, a methacrylate, an acrylate or an azide.

The at least one of the interlayer and the combined charge transport and emissive layer may further include a crosslinkable spacer material with one or more functional groups. The one or more functional groups of the interlayer and the combined charge transport and emissive layer may include an epoxide, an oxetane, an alkane, an alkene, an alkyne, a thiol, an aldehyde, a ketone, a carboxyl, a methacrylate, an acrylate or an azide.

The interlayer may be crosslinked to the combined charge transport and emissive layer through the crosslinked matrix formed at least partially from the at least one crosslinkable charge transport material other than the ligands. Also, the interlayer may be crosslinked to the combined charge transport and emissive layer through the ligands of the QDs.

The interlayer may also be crosslinked to the combined charge transport and emissive layer through the crosslinked matrix formed at least partially from the at least one crosslinkable charge transport material other than the ligands by the crosslinkable spacer material. In such a case, the interlayer may be crosslinked to the combined charge transport and emissive layer through the ligands of the QDs by the crosslinkable spacer material.

At least one of the combined charge transport and emissive layer and the interlayer further may include one or more initiators. At least one of the combined charge transport and emissive layer and the interlayer may also further comprise one or more photoinitiators. The at least one crosslinkable charge transport material may include one or more hole transport materials, and the apparatus may further comprise a hole transport layer disposed between the anode and the combined charge transport and emissive layer.

In some implementations, the apparatus may include a hole injection layer disposed between the anode and the hole transport layer. The apparatus may include an electron transport layer disposed between the cathode and the combined charge transport and emissive layer. Additionally, the at least one crosslinkable charge transport material may comprise at least one of a tertiary, secondary, or primary aromatic amine.

In another implementation, a light emitting structure includes a substrate, and a plurality of sub-pixel structures over the substrate. At least one of the plurality of sub-pixel structures includes an anode, a cathode, a combined charge transport and emissive layer disposed between the anode and the cathode and an interlayer of a material that has at least electron blocking properties disposed adjacent an upper outer surface of the combined charge transport and emissive layer. The combined charge transport and emissive layer includes quantum dots (QDs) with ligands, and the QDs are dispersed in a crosslinked matrix formed at least partially from at least one crosslinkable charge transport material other than the ligands.

The interlayer is formed by a crosslinked, crosslinkable material having one or more first functional groups. The one or more first functional groups comprise an epoxide, an oxetane, an alkane, an alkene, an alkyne, a thiol, an aldehyde, a ketone, a carboxyl, a methacrylate, an acrylate or an azide.

At least one of the plurality of sub-pixel structures may further include one or more electron injecting or transporting layers between the cathode and the combined charge transport and emissive layer, and one or more hole injecting or transporting layers between the anode and the combined charge transport and emissive layer.

### BRIEF DESCRIPTION OF THE DRAWINGS

Aspects of the exemplary disclosure are best understood from the following detailed description when read with the accompanying figures. Various features are not drawn to scale, dimensions of various features may be arbitrarily increased or reduced for clarity of discussion.

FIG. 1.1 is a first illustration of a two-dimensional schematic representation of a conventional core-shell quantum dot (QD).

FIG. 1.2 is a second illustration of a two-dimensional schematic representation of a conventional core-shell quantum dot (QD).

FIG. 2 illustrates the basic structure of a quantum dot light emitting diode (QLED) in elevation view.

FIG. 3.1 illustrates the layers of a standard QLED structure in an elevation view.

FIG. 3.2 illustrates the layers of an inverted QLED structure in an elevation view.

FIG. 4.1 illustrates a related art patterned QLED.

FIG. 4.2 illustrates a patterned QLED, showing an uneven QD dispersal.

FIG. 4.3 illustrates a patterned QLED with a thin interlayer of a material having at least electron blocking properties.

FIG. 5.1 illustrates an diagram with the energy levels for the constituents of a QLED having a standard structure.

FIG. 5.2A illustrates a diagram with the energy levels for the constituents of a QLED according to FIG. 4.1.

FIG. 5.2B illustrates a diagram with the energy levels for the constituents of a QLED according to FIG. 4.2.

FIG. 5.3 illustrates a diagram with the energy levels for the constituents of a QLED according to FIG. 4.3.

FIG. 6.1A illustrates a diagram with the energy levels for the constituents of a QLED with an interlayer material with hole and electron blocking properties.

FIG. 6.1B illustrates a diagram with the energy levels for the constituents of a QLED with an interlayer material with reduced hole and electron blocking properties.

FIG. 6.2A illustrates a diagram with the energy levels for the constituents of a QLED with an interlayer material with electron blocking properties.

FIG. 6.2B illustrates a diagram with the energy levels for the constituents of a QLED with an interlayer material with reduced electron blocking properties.

FIG. 6.3A illustrates a diagram with the energy levels for the constituents of a QLED with an interlayer material with hole blocking properties.

FIG. 6.3B illustrates a diagram with the energy levels for the constituents of a QLED with an interlayer material with reduced hole blocking properties.

FIG. 6.4A illustrates a portion of the interface between a CHTEL and an interlayer of the same material, before and after crosslinking.

FIG. 6.4B illustrates a portion of the interface between a CHTEL and an interlayer of a different material, before and after crosslinking.

FIG. 6.5A illustrates a portion of the interface between a CHTEL and an interlayer of the same material, including a spacer, before and after crosslinking.

FIG. 6.5B illustrates a portion of the interface between a CHTEL and an interlayer of a different material, including a spacer, before and after crosslinking.

FIG. 6.6 illustrates a portion of the interface between a CHTEL QD and an interlayer via ligands, before and after crosslinking.

FIG. 6.7 illustrates a portion of the interface between a CHTEL QD and an interlayer via ligands, including a spacer, before and after crosslinking.

FIG. 7.1 illustrates an elevation view of a QLED manufacturing process in which an anode is deposited on top of a substrate.

FIG. 7.2 illustrates an elevation view of a QLED manufacturing process in which at least one hole injecting/transporting layer (HIL/HTL) is deposited on the anode.

FIG. 7.3 illustrates an elevation view of a QLED manufacturing process in which a first combined hole transporting and emissive layer (CHTEL) layer is deposited.

FIG. 7.4 illustrates an elevation view of a QLED manufacturing process in which the first CHTEL layer is exposed to UV light only in a first area of the substrate.

FIG. 7.5 illustrates an elevation view of a QLED manufacturing process in which the deposited first CHTEL layer is rinsed with a solvent or developer.

FIG. 7.6 illustrates an elevation view of a QLED manufacturing process in which the first CHTEL layer remains only in the first area.

FIG. 7.7 illustrates an elevation view of a QLED manufacturing process in which a second CHTEL layer is deposited.

FIG. 7.8 illustrates an elevation view of a QLED manufacturing process in which the deposited second CHTEL layer is exposed to UV light only in a second area of the substrate.

FIG. 7.9 illustrates an elevation view of a QLED manufacturing process in which the deposited second CHTEL layer is rinsed with a solvent or developer.

FIG. 7.10 illustrates an elevation view of a QLED manufacturing process in which the second CHTEL layer remains only in the second area.

FIG. 7.11 illustrates an elevation view of a QLED manufacturing process in which a third CHTEL layer is deposited.

FIG. 7.12 illustrates an elevation view of a QLED manufacturing process in which the third CHTEL layer is exposed to UV light only in a third area of the substrate.

FIG. 7.13 illustrates an elevation view of a QLED manufacturing process in which the deposited third CHTEL layer is rinsed with solvent or developer.

FIG. 7.14 illustrates an elevation view of a QLED manufacturing process in which the third CHTEL layer remains only in the third area.

FIG. 7.15 illustrates an elevation view of a QLED manufacturing process in which an interlayer is deposited.

FIG. 7.16 illustrates an elevation view of a QLED manufacturing process in which the interlayer is exposed to UV light in the three areas of the substrate.

FIG. 7.17 illustrates an elevation view of a QLED manufacturing process in which an electron transporting layer (ETL) is deposited.

FIG. 7.18 illustrates an elevation view of a QLED manufacturing process in which a cathode layer is deposited to create three independent QLED sub-pixels.

FIG. 8.1 illustrates an elevation view of a QLED manufacturing process in which an anode is deposited on top of a substrate.

FIG. 8.2 illustrates an elevation view of a QLED manufacturing process in which at least one hole injecting/transporting layer (HIL/HTL) is deposited on the anode.

FIG. 8.3 illustrates an elevation view of a QLED manufacturing process in which a first combined hole transporting and emissive layer (CHTEL) layer is deposited.

FIG. 8.4 illustrates an elevation view of a QLED manufacturing process in which the first CHTEL layer is exposed to UV light only in a first area of the substrate.

FIG. 8.5 illustrates an elevation view of a QLED manufacturing process in which the deposited first CHTEL layer is rinsed with a solvent or developer.

FIG. 8.6 illustrates an elevation view of a QLED manufacturing process in which the first CHTEL layer remains only in the first area.

FIG. 8.7 illustrates an elevation view of a QLED manufacturing process in which a second CHTEL layer is deposited.

FIG. 8.8 illustrates an elevation view of a QLED manufacturing process in which the deposited second CHTEL layer is exposed to UV light only in a second area of the substrate.

FIG. 8.9 illustrates an elevation view of a QLED manufacturing process in which the deposited second CHTEL layer is rinsed with a solvent or developer.

FIG. 8.10 illustrates an elevation view of a QLED manufacturing process in which the second CHTEL layer remains only in the second area.

FIG. 8.11 illustrates an elevation view of a QLED manufacturing process in which the first CHTEL layer, the second CHTEL layer, and a third CHTEL layer are fixed in first, second and third areas.

FIG. 8.12 illustrates an elevation view of a QLED manufacturing process in which a first interlayer is deposited over the substrate.

FIG. 8.13 illustrates an elevation view of a QLED manufacturing process in which the first interlayer is exposed to UV light only in a first area of the substrate.

FIG. 8.14 illustrates an elevation view of a QLED manufacturing process in which the first interlayer is rinsed with solvent or developer.

FIG. 8.15 illustrates an elevation view of a QLED manufacturing process after the first interlayer is rinsed with solvent or developer.

FIG. 8.16 illustrates an elevation view of a QLED manufacturing process in which a second interlayer is deposited over the substrate.

FIG. 8.17 illustrates an elevation view of a QLED manufacturing process in which the second interlayer is exposed to UV light only in a second area of the substrate.

FIG. 8.18 illustrates an elevation view of a QLED manufacturing process in which the second interlayer is rinsed with solvent or developer.

FIG. 8.19 illustrates an elevation view of a QLED manufacturing process after the second interlayer is rinsed with solvent or developer.

FIG. 8.20 illustrates an elevation view of a first interlayer, second interlayer, and third interlayer are fixed in first, second, and third areas.

FIG. 8.21 illustrates an elevation view of a QLED manufacturing process in which an ETL and a cathode are deposited over the substrate.

FIG. 9.1 illustrates an elevation view of a QLED manufacturing process in which an anode is deposited on top of a substrate.

FIG. 9.2 illustrates an elevation view of a QLED manufacturing process in which at least one hole injecting/transporting layer (HIL/HTL) is deposited on the anode.

FIG. 9.3 illustrates an elevation view of a QLED manufacturing process in which a first combined hole transporting and emissive layer (CHTEL) layer is deposited.

FIG. 9.4 illustrates an elevation view of a QLED manufacturing process in which the first CHTEL layer is exposed to UV light only in a first area of the substrate.

FIG. 9.5 illustrates an elevation view of a QLED manufacturing process in which the deposited first CHTEL layer is rinsed with a solvent or developer.

FIG. 9.6 illustrates an elevation view of a QLED manufacturing process in which the first CHTEL layer remains only in the first area.

FIG. 9.7 illustrates an elevation view of a QLED manufacturing process in which a first interlayer is deposited.

FIG. 9.8 illustrates an elevation view of a QLED manufacturing process in which the first interlayer is exposed to UV light only in the first area.

FIG. 9.9 illustrates an elevation view of a QLED manufacturing process in which the first interlayer is rinsed with a solvent or developer.

FIG. 9.10 illustrates an elevation view of a QLED manufacturing process in which the first CHTEL and the first interlayer remain only in the first area.

FIG. 9.11 illustrates an elevation view of a QLED manufacturing process in which a second CHTEL is deposited.

FIG. 9.12 illustrates an elevation view of a QLED manufacturing process in which the second CHTEL is exposed to UV light only in a second area of the substrate.

FIG. 9.13 illustrates an elevation view of a QLED manufacturing process in which the second CHTEL is rinsed with a solvent or developer.

FIG. 9.14 illustrates an elevation view of a QLED manufacturing process in which the second CHTEL remains only in the second area.

FIG. 9.15 illustrates an elevation view of a QLED manufacturing process in which a second interlayer is deposited.

FIG. 9.16 illustrates an elevation view of a QLED manufacturing process in which the second interlayer is exposed to UV light only in the second area.

FIG. 9.17 illustrates an elevation view of a QLED manufacturing process in which the second interlayer is rinsed with a solvent or developer.

FIG. 9.18 illustrates an elevation view of a QLED manufacturing process in which the second interlayer remains only in the second area.

FIG. 9.19 illustrates an elevation view of a QLED manufacturing process in which a third CHTEL and a third interlayer remain only in a third area.

FIG. 9.20 illustrates an elevation view of a QLED manufacturing process in which and ETL and a cathode are deposited over the substrate.

FIG. 10 illustrates a top view of three QLED sub-pixels incorporated into a pixel, and further incorporated into a display.

FIG. 11 illustrates the crosslinkable material N4,N4′-Bis(4-(6-((3-ethyloxetan-3-yl)methoxy)hexyl)phenyl)-N4,N4′-diphenylbiphenyl-4,4′-diamine (OTPD).

FIG. 12 illustrates the crosslinkable material N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD).

FIG. 13 illustrates the crosslinkable material N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC).

FIG. 14 illustrates the crosslinkable material N4,N4′-Di(naphthalen-1-yl)-N4,N4′-bis(4-vinylphenyl)biphenyl-4,4′-diamine (VNPB).

FIG. 15 illustrates the crosslinkable material 9,9-Bis[4-[(4-ethenylphenyl) methoxy]phenyl-N2,N7-di-1-naphthalenyl-N2,N7-diphenyl-9H-Fluorene-2,7-diamine (VB-FNPD).

FIG. 16 illustrates the crosslinkable material 3,5-di-9H-carbazol-9-yl-N,N-bis[4-[[6-[(3-ethyl-3-oxetanyl)methoxy]hexyl]oxy]phenyl]-benzenamine (Oxe-DCDPA).

### DESCRIPTION

The following description contains specific information pertaining to exemplary implementations of the present disclosure. The drawings in the present disclosure and their accompanying detailed description are directed to merely exemplary implementations. However, the present disclosure is not limited to merely these exemplary implementations. Other variations and implementations of the present disclosure will occur to those skilled in the art. Unless noted otherwise, like or corresponding elements among the figures may be indicated by like or corresponding reference numerals. Moreover, the drawings and illustrations in the present disclosure are generally not to scale, and are not intended to correspond to actual relative dimensions.

For consistency and ease of understanding, like features are identified (although, in some examples, not shown) by numerals in the exemplary figures. However, the features in different implementations may differ in other respects, and thus shall not be narrowly confined to what is shown in the figures.

The description uses the phrases “in one implementation,” or “in some implementations,” which may each refer to one or more of the same or different implementations. The term “coupled” is defined as connected, whether directly or indirectly through intervening components, and is not necessarily limited to physical connections. The term “comprising,” when utilized, means “including, but not necessarily limited to”; it specifically indicates an open-ended inclusion or membership in the so-described combination, group, series and the equivalent.

Additionally, for purposes of explanation and non-limitation, specific details, such as functional entities, techniques, protocols, standards, and the like are set forth for providing an understanding of the described technology. In other examples, detailed description of well-known methods, technologies, system, architectures, and the like are omitted so as not to obscure the description with unnecessary details.

Disclosed is a specific structure of a quantum dot light emitting diode (QLED), a method to achieve it and a fabrication method to achieve multicolor high resolution displays based on QLEDs with this structure.

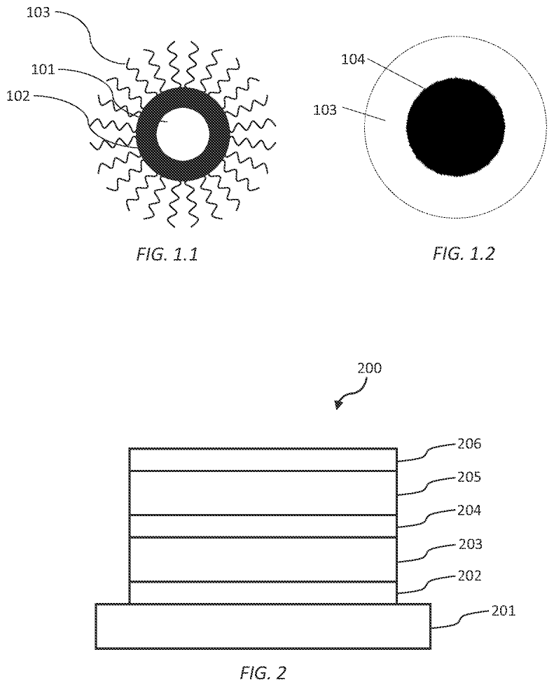

Referring to FIGS. 1.1 and 1.2, a two-dimensional schematic representation of a core-shell quantum dot (QD) is depicted as may be employed in an emissive layer. Quantum dots are defined as particles with a physical radius which is smaller than the exciton Bohr radius. The quantum dots may be configured as nanoparticles. A nanocrystalline core 101 is co-crystalized with a shell of a compatible material 102, which is then surrounded by ligands 103 that passivate crystal defects in the core-shell QD and allow and improve solubility in common solvents. FIG. 1.2 illustrates a schematic simplified version of FIG. 1.1 used for more convenient representation of QDs in a light-emitting apparatus structure, depicting a generalized core-shell QD structure 104 surrounded by a region of ligands 103.

It will be appreciated that while the present disclosure primarily describes the quantum dots as core-shell quantum dots, in some implementations the quantum dots may not be of the core-shell type or they may be of a core/multiple-shells type having more than one shell. The non-core-shell type quantum dots may be made from one or more of the above-mentioned materials, and the quantum dots in accordance with the present disclosure may not include a core-shell configuration.

Referring to FIG. 2, a basic structure of a QLED 200 is illustrated. A first electrode 202 is arranged on a substrate 201, with a second electrode 206 arranged opposite the first electrode 202 on the same side of the substrate 201. An emissive layer (EML) 204, which contains quantum dots (not shown), is arranged between the first electrode 202 and the second electrode 206, and is in electrical contact with the first electrode 202 and the second electrode 206.

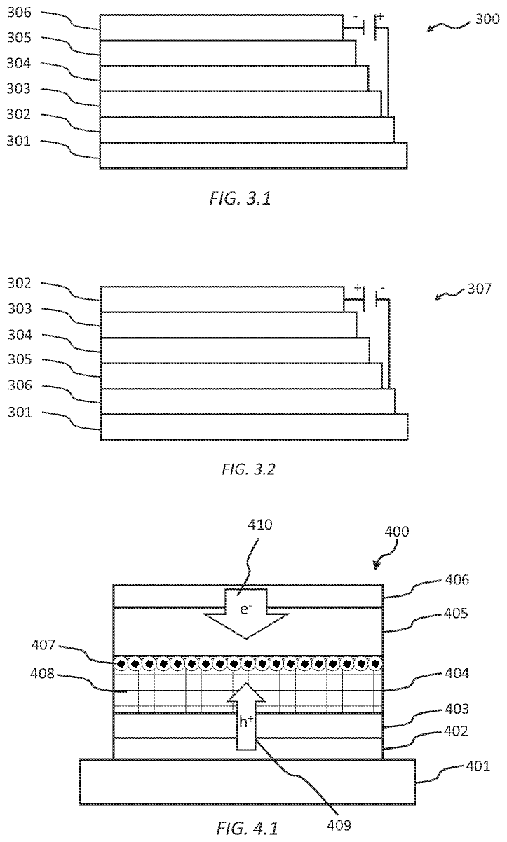

A first additional layer (first charge transport layer 203), and a second additional layer, (second charge transport layer 205) may be present between the first electrode 202, the second electrode 206, and the EML 204, such as one or more charge injection layers, charge transport layers and charge blocking layers. In a standard (or non-inverted) structure (as shown in FIG. 3.1) the electrode closer to the substrate (i.e., the first electrode 202) is an anode and any layers between the anode and the EML 204 are hole injection layers, hole transporting layers, electron blocking layers or hole blocking layers, together referred to as a first charge transport layer 203.

Similarly, the electrode further from the substrate (i.e., the second electrode 206) is a cathode and any layers between the cathode and the EML 204 are electron injection layers, electron transporting layers, hole blocking layers or electron blocking layers, together referred to as a second charge transport layer 205. The positions of the anode and cathode, along with all injection, transport and blocking layers (i.e., first charge transport layer 203, or second charge transport layer 205) may be reversed, in which case the apparatus is said to have an inverted structure (as shown in FIG. 3.2).

FIG. 3.1 illustrates the layers of a standard (or non-inverted) QLED 300, including the polarity of an electronic circuit applied thereto. The standard QLED 300 includes a substrate 301, with an anode layer 302 formed on the substrate 301. A hole transporting layer(s) 303 is formed on the anode layer 302. An EML 304 (including QDs) is formed on the hole transporting layer(s) 303. An electron transporting layer(s) 305 is formed on the EML 304, and a cathode layer 306 is formed over the electron transporting layer(s) 305.

FIG. 3.2 illustrates the layers of an inverted QLED 307, including the polarity of an electronic circuit applied thereto. The inverted QLED 307 includes a substrate 301, with a cathode layer 306 formed on the substrate 301. An electron transporting layer(s) 305 is formed on the cathode layer 306. An EML 304 (including QDs) is formed on the electron transporting layer(s) 305. A hole transporting layer(s) 303 is formed on the EML 304, and an anode layer 302 is formed over the hole transporting layer(s) 303.

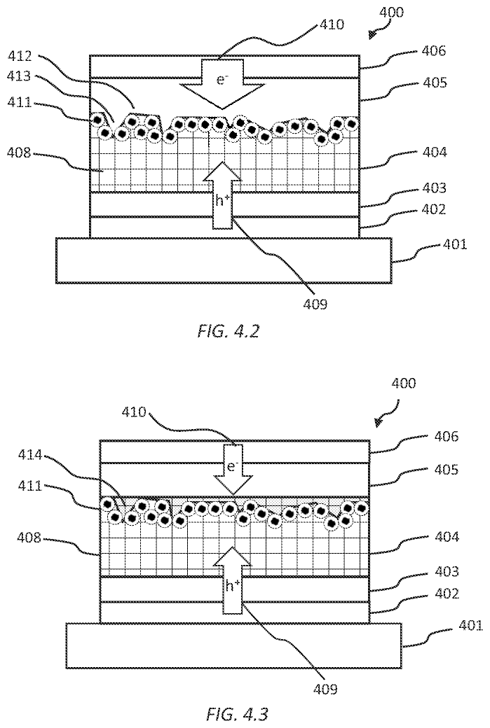

Referring to FIG. 4.1 a standard top emitting QLED structure 400 is shown as per an implementation in Angioni et al. (U.S. Pat. No. 10,581,007). The QLED structure 400 comprises various layers sandwiched between two electrodes, deposited in the following order: an anode layer 402 is deposited on a substrate 401, a hole injection layer (HIL) 403 is deposited on the anode layer 402, a combined hole transporting and emissive layer (CHTEL) 404 is deposited on the HIL 403, an electron transporting layer (ETL) 405 is deposited on the CHTEL 404 and a cathode layer 406 is deposited on the ETL 405.

The CHTEL 404 comprises a series of quantum dots 407, dispersed and mainly phase segregated as monolayer on the upper outer surface of a crosslinked hole transporting material 408 that makes them patternable and resistant to solvent rinsing. Electron mobility 410 from the cathode layer 406, and hole mobility 409 from the anode layer 402 are shown moving toward the CHTEL 404 to produce luminance. In practice, the morphology of the resulting CHTEL 404 as shown in FIG. 4.1 is not always ideal.

Referring to FIG. 4.2, a more realistic representation of the CHTEL 404 is illustrated, where the QDs 411 are not distributed as a uniform monolayer, and the outer upper surface of the CHTEL 404 is rough (uneven), forming concave areas 412 and convex areas 413 due to the intrinsic properties of the QDs.

Furthermore, as stated in the related art, the structure shown in FIG. 4.2 (and FIG. 4.1) reflects the imbalance of the hole mobility 409 and the electron mobility 410, with the hole mobility 409 being lower than the electron mobility 410. This kind of structure has even lower hole mobility 409 compared with a QLED structure with the emissive layer deposited from colloidal QDs, making the transport of charge carriers even less efficient than in a pure material. The lower hole mobility 409, is affected because the hole transporting material surrounds the QDs. This has a negative effect because the hole transporting material can directly contact the electron transporting layer creating non-radiative pathways. However, at the same time it has positive effect because the holes are transported more effectively to the QDs.

Referring to FIG. 4.3, in order to improve the morphology of the CHTEL 404 and simultaneously improve the hole mobility 409/electron mobility 410 balance (and consequently the performance of the apparatuses created with this kind of structure), a strategy has been developed involving the deposition of a thin interlayer 414 of material that has at least electron blocking properties. This has the dual effect of leveling the CHTEL 404 creating a flatter surface on which to deposit the ETL 405 and to provide an electron blocking barrier in order to balance the holes and electrons injected in the QDs (i.e., hole mobility 409 and electron mobility 410).

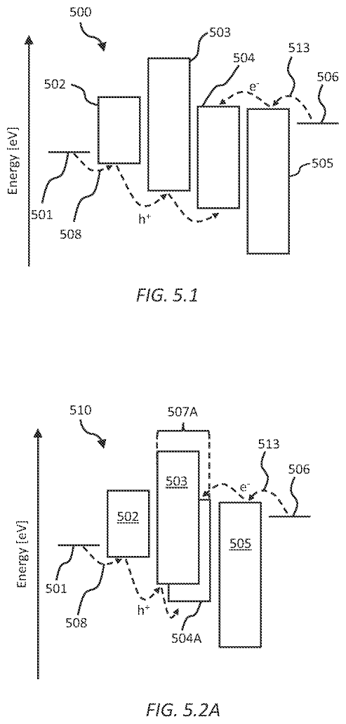

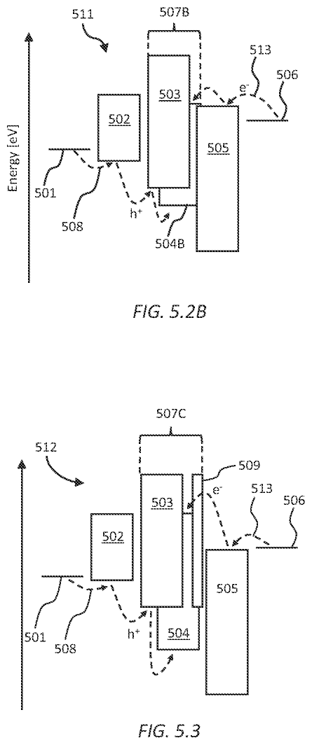

Referring to FIG. 5.1, a first diagram 500 of an QLED apparatus is shown illustrating the energy levels of the different constituents of the QLED, having a standard structure as is known in the related art. The constituent layers include an anode layer 501, a HIL 502, an HTL 503, an EML 504, an ETL 505 and a cathode layer 506.

Referring to FIG. 5.2A, a second diagram 510 of the QLED apparatus of FIG. 4.1 is shown illustrating the energy levels of the different constituents of the QLED having a standard structure as is known in the related art. The constituent layers include an anode layer 501, an HIL 502, a CHTEL 507A composed of quantum dots 504A dispersed and mainly phase segregated on the top of a crosslinkable hole transporting material of an HTL 503, an ETL 505 and a cathode layer 506.

Referring to FIG. 5.2B, a third diagram 511 of the QLED apparatus of FIG. 4.2 is shown illustrating the energy levels of the different constituents of the QLED having a standard structure as is known in the related art. The constituent layers include an anode layer 501, an HIL 502, a CHTEL 507B composed of quantum dots 504B dispersed and mainly phase segregated on the top of a crosslinkable hole transporting material of an HTL 503, an ETL 505 and a cathode layer 506. In this case the ETL 505 is partially surrounding the QDs of the EML 504, and thus is much closer to the crosslinkable hole transporting material. In this structure, there may be non-radiative pathways that go directly from the ETL 505 to the crosslinkable hole transporting material of the HTL 503, thereby decreasing the overall performance of the apparatus.

Referring to FIG. 5.3, a fourth diagram 512 of the QLED apparatus of FIG. 4.3 is shown illustrating the energy levels of different constituents of the QLED having a standard structure. The constituent layers include an anode layer 501, an HIL 502, a CHTEL 507C, an ETL 505 and a cathode layer 506. The CHTEL 507C is composed of QDs 504C dispersed and mainly phase segregated on the top of a mixture of a crosslinkable hole transporting material of an HTL 503. Additionally, is present a thin electron blocking interlayer 509 of material that is at least electron blocking with the order described in FIG. 4.3 (i.e., interlayer 414 on top of the QDs 411).

In these QLED structures (FIGS. 5.1, 5.2A, 5.2B, 5.3), when a positive bias is applied to the apparatus, holes 508 and electrons 513 travel as depicted by the dotted arrows, and they meet at the QDs where they recombine and emit light. In the apparatus depicted in FIG. 5.1 the holes 508 and electrons 513 have to travel passing through the different layers, encountering differences in energies and mobility from the different materials. In the structure depicted in FIG. 5.2A there is an improvement in the path of for the holes 508. For example, the HTL 503 is now crosslinked and disperses the QDs 504A. This makes these two materials more interconnected improving the transport of holes into the QDs 504A.

In the apparatus depicted in FIG. 5.2B the improvement described in FIG. 5.2A is worsened by the fact that the morphology of the CHTEL 507B is not ideal but it is more like as depicted in FIG. 4.2. This brings the ETL 505 closer to the crosslinkable material of the HTL 503, increasing the chance of non-radiative pathways between these two layers and then decreasing the performances of the apparatus.

In the apparatus depicted in FIG. 5.3 the not radiative pathways between the ETL 505 and the crosslinkable hole transporting material of the HTL 503 are at least partially blocked by the insertion of the electron blocking interlayer 509. In this structure, the injection of electrons 513 into the QDs is decreased and a hole-electron balance is achieved.

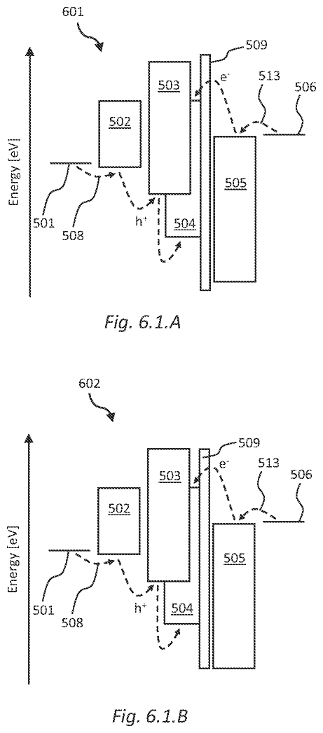

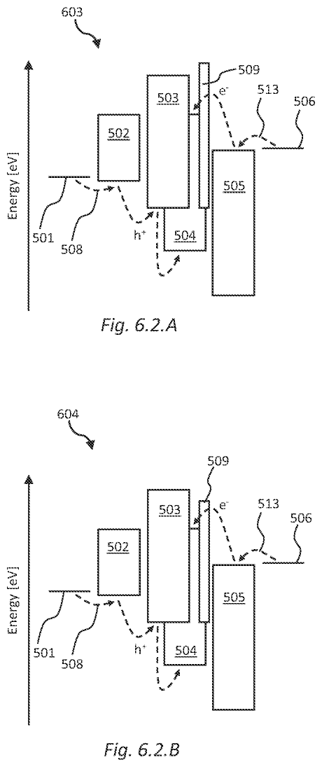

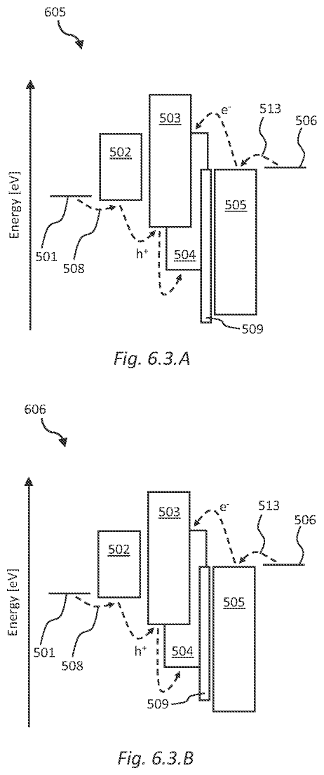

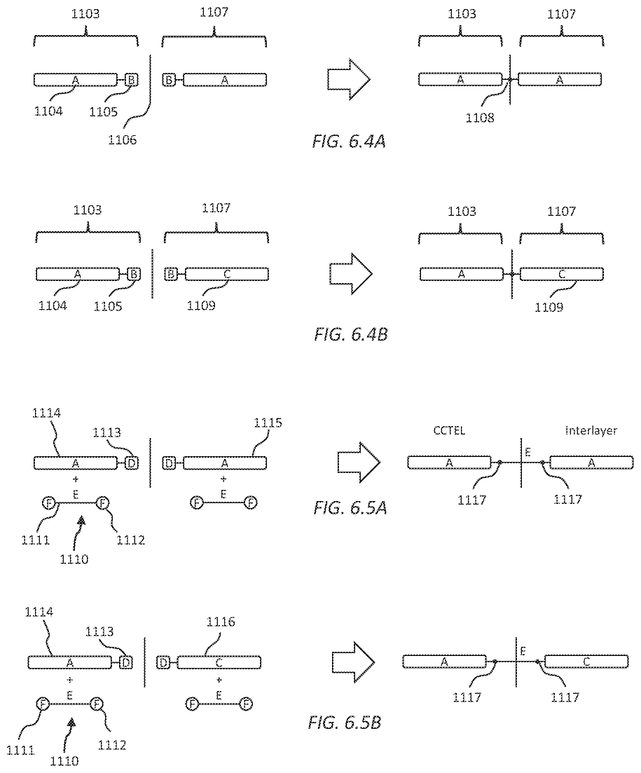

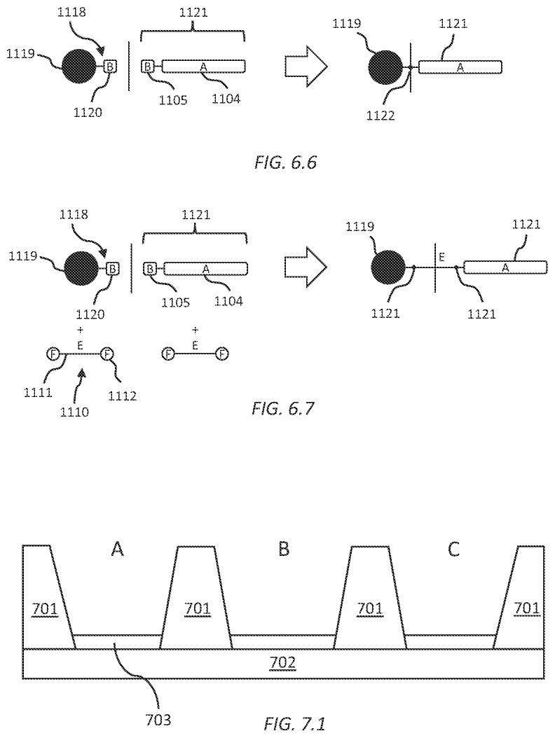

The benefits of the structure shown in FIG. 5.3 depend on:
(1) Absolute and relative energy levels of the HTL 503, the QDs of the EML 504 (i.e., in the EML), the ETL 505 and the electron blocking interlayer 509. Considering energy levels as depicted as in FIGS. 5.2A and 5.2B, the interlayer 509 should have conduction energy level (LUMO energy if organic) higher than that of the ETL 505. The larger this difference in energy is, the larger will be the capacity of the interlayer 509 to block electrons, and the electrons will be injected in the QDs less efficiently.
(2) The valence energy level (or HOMO level if organic) of the material of the interlayer 509, can be equal, higher or lower of that of the crosslinkable hole transporting material of the HTL 503, depending on what kind of variation of mobility is desired.
   (a) If a general decrease in mobility is needed, both for holes and electrons at an interface, then an interlayer 509 with lower valence energy level (or HOMO level if organic) and higher conduction energy level (LUMO energy if organic) is needed (See, e.g., FIG. 6.1.A and FIG. 6.1.B below).
   (b) If only lower electron mobility at an interface is needed, then an interlayer 509 with higher conduction energy level (LUMO energy if organic) is needed (See, e.g., FIG. 6.2.A and FIG. 6.2.B below).
   (c) If only lower hole mobility at an interface is needed, then an interlayer 509 with lower valence energy level (or HOMO level if organic) is needed (See, e.g., FIG. 6.3.A and FIG. 6.3.B below).
(3) If the interlayer 509 is made of a crosslinkable material (the same as the HTL 503 or different), it can be patterned on a specific area of the apparatus. This aspect is of particular importance in order to include QLEDs with this structure in multicolor high resolution displays, For example, as described in the related art and later in this disclosure for implementations of this disclosure, three different types of QDs on three different regions of a substrate should be deposited such that each region emits light (through electrical injection; i.e. by electroluminescence) in three different colors, particularly red (R), green (G) and blue (B). Sub-pixels that respectively emit red, green, or blue light may collectively form a pixel, which in turn may be a part of an array of pixels of a display. Different materials can be used for the three different colors, depending on the energy levels of the different QDs used and of the different crosslinkable material. Furthermore, the interlayer 509 can be used as protective barrier for the QDs 504C that have to withstand multiple depositions of other layers and rinsing steps in order to prepare QLEDs with this structure in multicolor high resolution displays, as described below.

The CHTEL 404 (FIG. 4.3) described above has thickness from 10 to 150 nm and it is composed by QDs 411 (from 1 to 40 wt % of the mixture) and the crosslinked hole transporting material 408 (from 60 to 99 wt % of the mixture). In implementations where an initiator of the polymerization (crosslinkage) is included, this has a concentration from 0.01 wt % to 10 wt % of the electron blocking interlayer 414. The total concentration of materials in the solution used to deposit this layer is between 0.1 to 20 wt % with the solvent being 99.9 to 80 wt %.

Preferred values for the thickness and the composition of the CHTEL 404 are: 20-80 nm; QDs 411 (15-25 wt %), crosslinked hole transporting material 408 (75-85 wt %). In implementations where initiator of the polymerization (crosslinkage) is included, ideal values are 1-3 wt %. The ideal total concentration of materials in the solution used to deposit the CHTEL 404 is between 1 to 5 wt % with the solvent being 99 to 95 wt %.

The final thin interlayer 414 described above has thickness from 0.5 to 10 nm. In implementations where the interlayer 414 is composed by a crosslinkable material and an initiator of the polymerization (crosslinkage) is included, ideal values of composition of the layer are: initiator from 1-3 wt %, crosslinkable material from 99.9 to 97 wt %.

Implementations:

Patternable QLED with Interlayer for Reduced Hole and Electron Mobility

Referring to FIGS. 6.1A and 6.1B, a diagram illustrating the energy levels of a patternable QLED with interlayer for reduced hole and electron mobility is shown. The interlayer 509 in this context has both hole blocking and electron blocking properties, with valence energy level (or HOMO level if organic) similar to the one of the ETL 505 and conduction energy level (LUMO energy if organic) similar to the one of the crosslinkable hole transporting material of the HTL 503 (FIG. 6.1.B).

The interlayer 509 can be an organic or inorganic material or a polymer with large band gap or it can be a mixture of two or more materials. In one implementation, the two materials are the same ETL 505 and crosslinkable HTL 503 used in the specific QLED. The composition of the resulting interlayer 509 is the ETL 505 (1 to 99 wt %) and crosslinkable HTL 503 (1 to 99 wt %). Ideal composition is of the resulting interlayer 509 is ETL 505 (30 to 70 wt %) and crosslinkable HTL 503 (30 to 70 wt %).

In extreme versions of this implementation, the interlayer 509 is composed by or partially composed by an insulating material (FIG. 6.1.A), with valence energy level (or HOMO level if organic) lower than the one of the ETL 505 and conduction energy level (LUMO energy if organic) higher than the one of the crosslinkable HTL 503.

Patternable QLED with Interlayer with Electron Blocking Properties

Referring to FIGS. 6.2A and 6.2B, a diagram illustrating the energy levels of a patternable QLED with interlayer with electron blocking properties is shown. The interlayer 509 in this context has electron blocking properties, with conduction energy level (LUMO energy if organic) similar to the one of the crosslinkable hole transporting material of the HTL 503. The interlayer 509 can be an organic or inorganic material or it can be a mixture of two or more materials. In the simplest implementation, the material is the same X-HTM or is another material with similar energy levels to the HTL 503.

In another implementation, the two materials are the same X-HTM and another material with similar energy levels to the HTL 503. The composition of the resulting interlayer 509 is X-HTM (1 to 99 wt %) and other material with similar energy levels to the HTL 503 (1 to 99 wt %). An ideal composition of the resulting interlayer 509 is X-HTM (30 to 70 wt %) and other material with similar energy levels then the HTL 503 (30 to 70 wt %). Depending on the energy levels of the material with similar energy levels to the HTL 503, the electron blocking capacity of the interlayer 509 can be reduced, the conduction energy level (LUMO energy if organic) of the interlayer 509 is reduced (FIG. 6.2.B).

Patternable QLED with Interlayer with Hole Blocking Properties

Referring to FIGS. 6.3A and 6.3B, a diagram illustrating the energy levels of a patternable QLED with interlayer with hole blocking properties is shown. The interlayer 509 in this context has hole blocking properties, with valence energy level (HOMO energy if organic) similar to the one of the electron transporting material of the ETL 505. The interlayer 509 can be an organic or inorganic material or it can be a mixture of two or more materials. In the simplest implementation, the material is the same electron transporting material or is another material with similar energy levels than the ETL 505.

In another implementation, the two materials are the same ETM as the ETL 505 and another material with similar energy levels to the ETL 505. The composition of the resulting interlayer 509 is ETM of the ETL 505 (1 to 99 wt %) and other material with similar energy levels to the ETL 505 (1 to 99 wt %). An ideal composition is of the resulting interlayer 509 is ETM of the ETL 505 (30 to 70 wt %) and other material with similar energy levels to the ETL 505 (30 to 70 wt %). Depending on the energy levels of the material with similar energy levels to the ETL 505, the hole blocking capacity of the interlayer 509 can be reduced, the conduction energy level (LUMO energy if organic) of the interlayer 509 is reduced (FIG. 6.3.B).

Patternable QLED with Interlayer Crosslinked with the CHTEL Matrix

Referring to FIGS. 6.4A and 6.4B, a diagram illustrating a patternable QLED with interlayer crosslinked with the CHTEL matrix, including a portion of the interface between the CHTEL 404 and the interlayer 414 as depicted in FIG. 4.3. In this implementation, the interlayer 414 may crosslink with the crosslinked hole transporting material 408 of the CHTEL 404. The interlayer 414 contains an interlayer material 1107 with the same crosslinkable functional groups of the charge transporting material 1103 that forms the crosslinked hole transporting material 408 of the CHTEL 404. The crosslinkable charge transporting material 1103 is depicted in FIGS. 6.4A and 6.4B and can be descripted as a material with a charge transporting moiety A 1104 and at least one moiety B 1105 that provide crosslinking capabilities. When the interlayer 414 is exposed to an external stimulus (e.g. light, temperature, pressure, etc.) polymerization between the interlayer material 1107 and the charge transporting material 1103 matrix happens creating bonds 1108 as depicted in the second part of the FIG. 6.4A. In one exemplary implementation represented in FIG. 6.4A the interlayer 414 is made from the same material that constitute the crosslinked hole transporting material 408 of the CHTEL 404 (i.e., 1103 is equal to 1107).

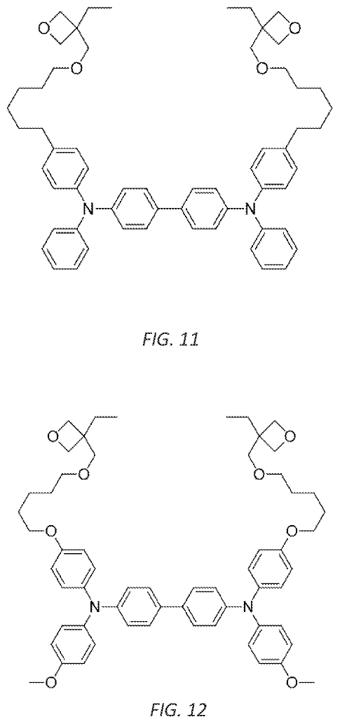

In another exemplary implementation represented in FIG. 6.4B the interlayer 414 is made from a similar material (i.e., 1103 is different from 1107) to that constituting the crosslinked hole transporting material 408 of the CHTEL 404. Two similar materials, as described in this implementation, contain different charge transporting moieties (i.e., moiety C 1109 is different from moiety A 1104 in FIG. 11.1B) and the same moiety B that provide crosslinking capabilities.

In some implementations also an initiator is added and through an external stimulus (e.g. light, temperature, pressure, etc.) it initiate the polymerization. In one implementation the external stimulus that initiate the polymerization is UV light. In one implementation, the CHTEL material 1103 and the interlayer material 1107 contain an initiator of the polymerization. In one implementation the initiator is a photo initiator and it is present in both the interlayer 414 and the crosslinked hole transporting material 408 of the CHTEL 404. In another implementation the initiator is present only in one of the interlayer 414 and the crosslinked hole transporting material 408 of the CHTEL 404.

In one implementation the functional groups B can be oxetanes. In some implementations, not represented, the functional groups B are different. In one implementation of these implementations, one of the functional groups B is a thiol and the other is an alkene, or vice versa. Exemplary UV-induced crosslinkable charge transport material are reported in the materials description section below.

Patternable QLED with Interlayer Crosslinked with the CHTEL Matrix Through a Spacer

Referring to FIGS. 6.5A and 6.5B, a diagram illustrating a patternable QLED with interlayer crosslinked with the CHTEL matrix through a spacer, including a portion of the interface between the CHTEL 404 and the interlayer 414 as depicted in FIG. 4.3 is shown.

In this implementation, the interlayer 414 may crosslink with the crosslinked hole transporting material 408 of the CHTEL 404 through a spacer 1110. The interlayer 414 contains an interlayer material 1115 with the same crosslinkable functional groups of the matrix material 1114 that forms the crosslinked hole transporting material 408 of the CHTEL. The crosslinkable charge transporting material as depicted in FIGS. 11.2A and 11.2B can be descripted as a material with a charge transporting moiety A 1104 and at least one moiety D 1113 that provide crosslinking capabilities. The spacer 1110 as depicted in FIGS. 11.2A and 11.2B can be descripted as a material with a carbon based backbone E 1111 and at least two moieties F 1112 that provide crosslinking capabilities. In one implementation the spacer 1110 is present in both the CHTEL and in the interlayer. In another implementation the spacer 1110 is present in only one of the CHTEL and the interlayer.

When the interlayer 414 is exposed to an external stimulus (e.g. light, temperature, pressure, etc.) polymerization between the interlayer material 1115, the spacer 1110 and the matrix material 1114 happens creating bonds 1108 as depicted in the second part (right) of the FIG. 6.5A. In one exemplary implementation represented in FIG. 6.5A the interlayer 414 is made from the same material (i.e., matrix material 1114 equals interlayer material 1115) that constitute the crosslinked hole transporting material 408 of the CHTEL 404 and the spacer 1110 is the same in the CHTEL 404 and in the interlayer 414. In another exemplary implementation (not represented) the interlayer 414 is made from the same material (i.e., matrix material 1114 equals interlayer material 1115) that constitute the crosslinked hole transporting material 408 of the CHTEL 404 and the spacer 1110 in the CHTEL 404 and in the interlayer 414 is different.

In one exemplary implementation represented in FIG. 6.5B the interlayer 414 is made from a different material (i.e., matrix material 1114 differs from interlayer 1116) that constitute the crosslinked hole transporting material 408 of the CHTEL 404 and the spacer 1110 is the same in the CHTEL 404 and in the interlayer 414. In another exemplary implementation (not represented) the interlayer 414 is made from a different material (i.e., matrix material 1114 differs from interlayer material 1116) that constitute the crosslinked hole transporting material 408 of the CHTEL 404 and the spacer 1110 in the CHTEL 404 and in the interlayer 414 is different.

In one exemplary implementation represented in FIG. 6.5B the interlayer 414 is made from a similar material (1103 different from 1107) to that constituting the crosslinked hole transporting material 408 of the CHTEL 404. Two similar materials, as described in this implementation, contain different charge transporting moieties (i.e., moiety C 1109 is different from moiety A 1104 in FIG. 11.1B) and the same moiety B that provide crosslinking capabilities.

In one implementation the external stimulus that initiate the polymerization is UV light. In one implementation, the CHTEL 404 and the interlayer 414 contain an initiator of the polymerization. In one implementation the initiator is a photo initiator and it is present in both the interlayer 414 and the crosslinked hole transporting material 408 of the CHTEL 404. In another implementation the initiator is present only in one of the interlayer 414 and the crosslinked hole transporting material 408 of the CHTEL 404.

In some implementations, also an initiator is added and through an external stimulus (e.g. light, temperature, pressure, etc.) it initiate the polymerization. In one implementation the external stimulus that initiate the polymerization is UV light. In one implementation, the CHTEL 404 and the interlayer 414 contain an initiator of the polymerization. In one implementation the initiator is a photo initiator and it is present in both the interlayer 414 and the crosslinked hole transporting material 408 of the CHTEL 404. In another implementation the initiator is present only in one of the interlayer 414 and the crosslinked hole transporting material 408 of the CHTEL 404.

Exemplary UV-induced crosslinkable charge transport material and crosslinkable spacers including such functional groups are reported below in the materials description. In one implementation, the functional groups F may be a thiol, and the function groups D may be an alkene or alkyne, or vice versa. Exemplary UV-induced crosslinkable charge transport material and spacers including such functional groups are reported below in the materials description section.

Patternable QLED with Interlayer Crosslinked with the CHTEL QDs Via Ligands

Referring to FIG. 6.6, a diagram illustrating a patternable QLED with interlayer crosslinked with the CHTEL via ligands, including a portion of the interface between the CHTEL 404 and the interlayer 414 as depicted in FIG. 4.3 is shown. In this implementation, the interlayer 414 may crosslink with the ligands 1118 of the QDs 411. The interlayer 414 contains a crosslinkable charge transporting material 1121 with crosslinkable functional groups that can be descripted as a material with a charge transporting moiety A 1104 and at least one moiety B 1105 that provides crosslinking capabilities. The ligands 1118 of an individual QD 1119 can be described as a material with at least one moiety B 1120 that provides crosslinking capabilities.

When the Interlayer 414 is exposed to an external stimulus (e.g. light, temperature, pressure, etc.) polymerization between the interlayer material 1121 and the ligands 1118 of the QDs 1119 happens creating bonds 1122 as depicted in the second part of the FIG. 6.6. In one exemplary implementation represented in FIG. 6.4A, the moiety B 1105 of the material 1121 of the interlayer 414 is the same of the moiety B 1120 of the ligands 1118 of the QD 1119.

In one implementation, the functional groups B can be oxetanes. In another exemplary implementation, not represented, the moiety 1105 of the material 1121 of the interlayer (FIG. 6.4A) is different from the moiety B 1120 of the ligands 1118 of the QD 1119. In one implementation of this implementation, one of the functional groups B is a thiol and the other is an alkene, or vice versa.

In some implementations also an initiator is added and through an external stimulus (e.g. light, temperature, pressure, etc.) it initiate the polymerization. In one implementation the external stimulus that initiate the polymerization is UV light. In one implementation, the CHTEL 404 and the interlayer 414 contain an initiator of the polymerization. In one implementation the initiator is a photo initiator and it is present in both the interlayer 414 and the crosslinked hole transporting material 408 of the CHTEL 404. In another implementation the initiator is present only in one of the interlayer 414 and the crosslinked hole transporting material 408 of the CHTEL 404. Exemplary UV-induced crosslinkable charge transport material and crosslinkable ligands including such functional groups are reported in the materials description section below.

Patternable QLED with Interlayer Crosslinked with the CHTEL QDs Via Spacer

Referring to FIG. 6.7, a diagram illustrating a patternable QLED with interlayer 414 crosslinked with the CHTEL 404 via spacer, including a portion of the interface between the CHTEL 404 and the interlayer 414 as depicted in FIG. 4.3 is shown. In this implementation, the interlayer 414 may crosslink with the ligands 1118 of the QDs 411 through a spacer 1110. The interlayer 414 contains a crosslinkable charge transporting material 1121 with crosslinkable functional groups that can be descripted as a material with a charge transporting moiety A 1104 and at least one moiety B 1105 that provides crosslinking capabilities. The moiety B 1120 of the QD 1119 can be described as a material with at least one moiety B 1120 that provides crosslinking capabilities. The spacer 1110 as depicted in FIG. 6.7 can be descripted as a material with a carbon based backbone E 1111 and at least two moieties F 1112 that provide crosslinking capabilities. In one implementation the spacer 1110 is present in both the CHTEL 404 and in the interlayer 414. In another implementation the spacer 1110 is present in only one of the CHTEL 404 and the interlayer 414.

When the interlayer 414 is exposed to an external stimulus (e.g. light, temperature, pressure, etc.) polymerization between the interlayer material 1121, the spacer 1110 and the moiety B 1120 of the QD 1119 happens creating bonds 1122 as depicted in the second part (right) of the FIG. 6.7. In one exemplary implementation represented in FIG. 6.7 the interlayer 414 is made from a material with the same crosslinkable functional group of the Moiety B 1120 of the QD 1119 (i.e., moiety B 1120 equals moiety B 1105) and the spacer 1110 is the same in the CHTEL 404 and in the interlayer 414.

In another exemplary implementation (not represented) the interlayer 414 is made from a material with the same crosslinkable functional group of the moiety B 1120 of the QD 1119 (i.e., moiety B 1120 equal moiety B 1105) and the spacer 1110 in the CHTEL 404 and in the interlayer 414 is different. In one exemplary implementation (not represented) the interlayer 414 is made from a material with a different crosslinkable functional group from the Moiety B 1120 of the QD 1119 (i.e., moiety B 1120 differs from moiety B 1105) and the spacer 1110 is the same in the CHTEL 404 and in the interlayer 414.

In one exemplary implementation (not represented) the interlayer 414 is made from a material with a different crosslinkable functional group from the moiety B 1120 of the QD 1119 (i.e., moiety B 1120 differs from moiety B 1105) and the spacer 1110 in the CHTEL 404 and in the interlayer 414 is different.

In some implementations also an initiator is added and through an external stimulus (e.g. light, temperature, pressure, etc.) it initiate the polymerization. In one implementation the external stimulus that initiate the polymerization is UV light. In one implementation, the CHTEL 404 and the interlayer 414 contain an initiator of the polymerization. In one implementation the initiator is a photo initiator and it is present in both the interlayer 414 and the crosslinked hole transporting material 408 of the CHTEL 404. In another implementation the initiator is present only in one of the interlayer 414 and the crosslinked hole transporting material 408 of the CHTEL 404.

In one implementation, the functional groups F may be a thiol, and the function groups B may be an alkene or alkyne, or vice versa. Exemplary UV-induced crosslinkable charge transport material, ligands and spacers including such functional groups are reported in the materials description section below.

RGB Patterned QLEDs with Shared Interlayer

Referring to 7.1-7.18, various manufacturing actions are shown in creating RGB patterned QLEDs with a shared interlayer. The method (not to scale) uses the above disclosed structures in order to form three different QLEDs with standard structure on three different regions of a substrate. The three different areas may be sub-pixels that respectively emit light of three different colors and that may collectively form a pixel, which in turn may be a part of an array of pixels of the display. These three structures can share the same interlayer on top of three different CHTELs representing different colors. In this implementation, it is deposited only when all three different CHTELs are already deposited.

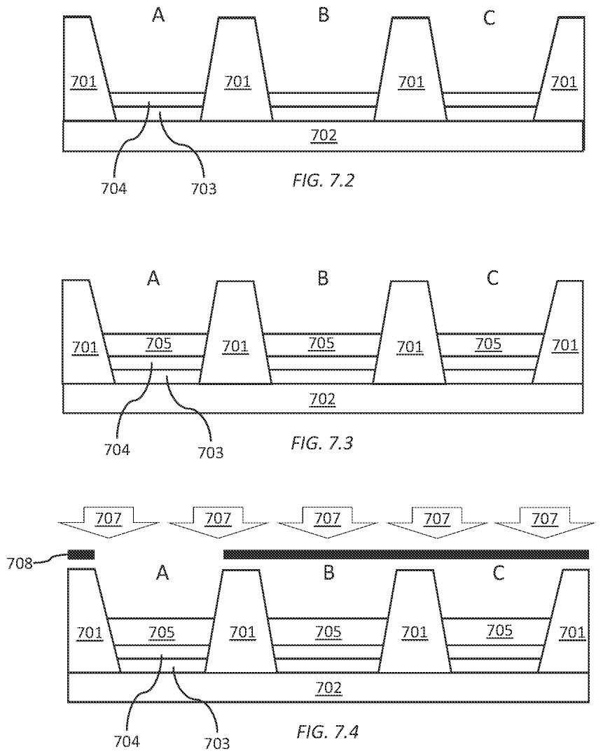

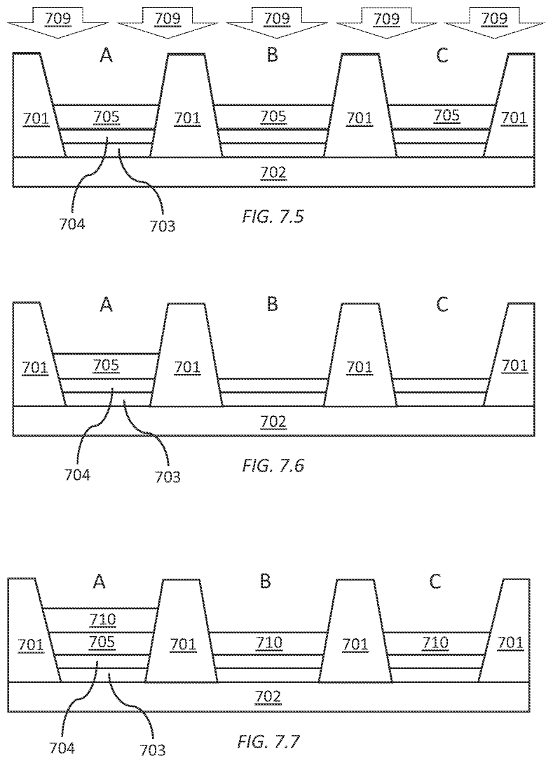

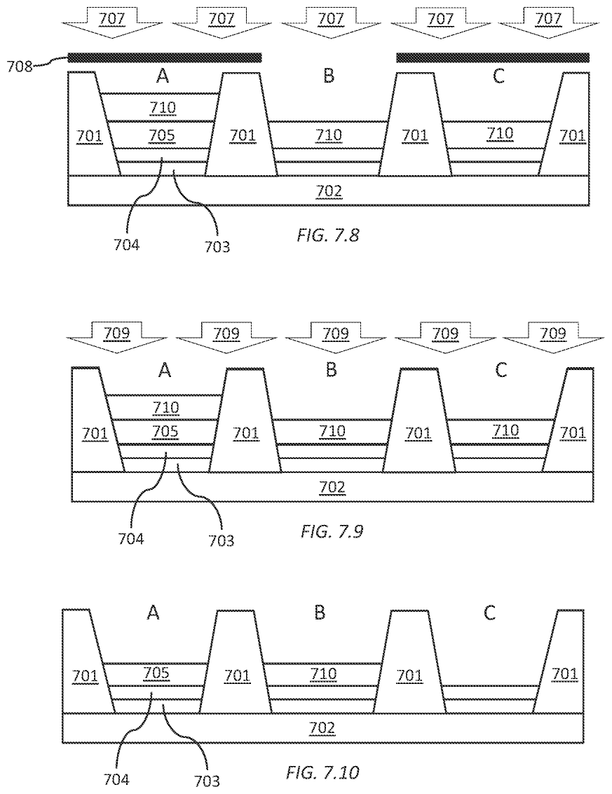

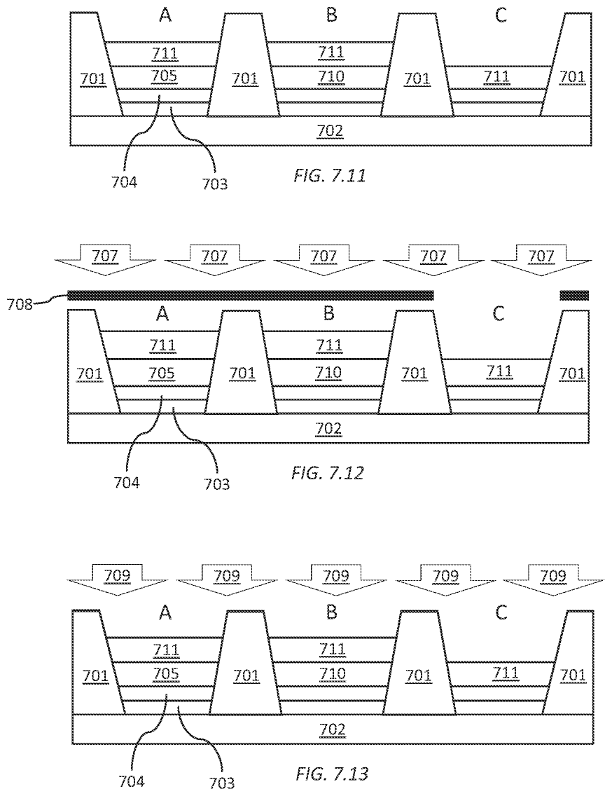

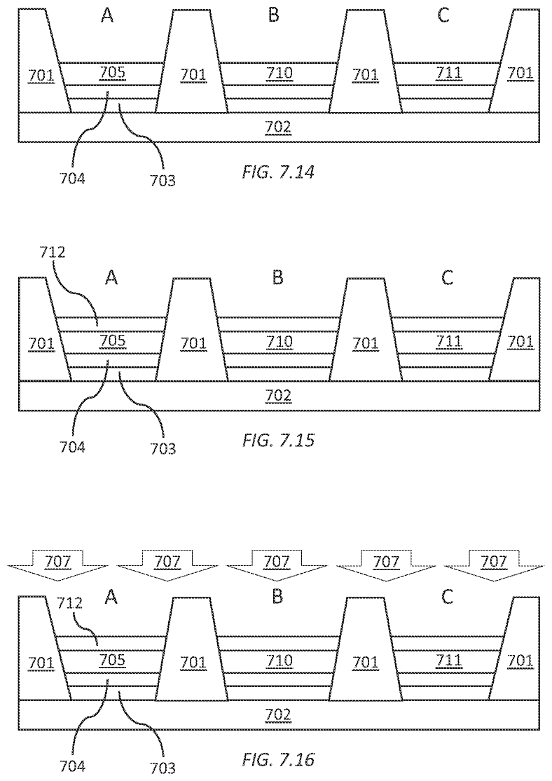

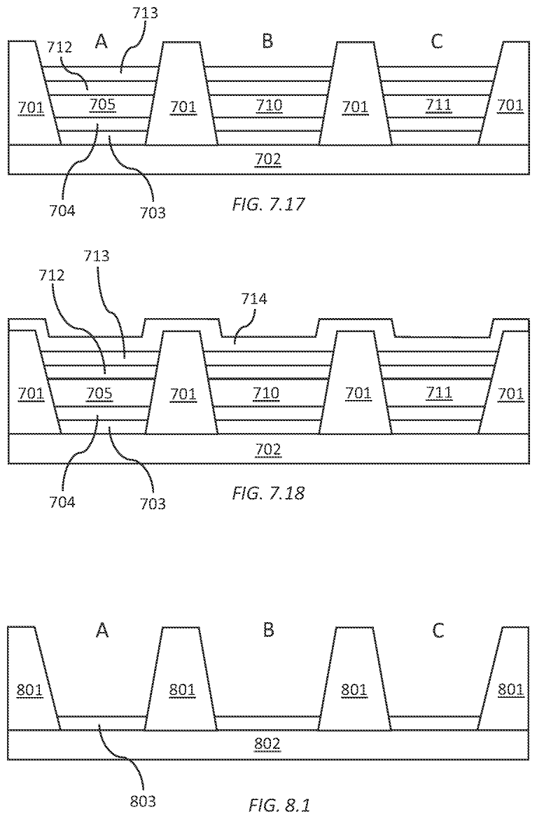

Light-emitting apparatuses may be arranged such that the light-emitting apparatuses are separated at least in part by one or more insulating materials. This arrangement may also be referred to as a “bank structure.” FIGS. 7.1-7.18 are drawings illustrating a cross-section view of such a bank structure 701 that can allocate multiple light-emitting apparatuses formed in accordance with implementations of the present application. In a specific implementation these areas are three and they are labeled A, B and C in order to distinguish three different sub-pixels. They are formed in these areas by taking, at least the following actions:

FIG. 7.1 shows that an anode layer 703 is deposited on top of a substrate 702 with bank structures 701 shaped in order to accommodate three different sub-pixels (i.e., A, B, and C). The anode layer 703 can be the same in the three areas or different for each area.

FIG. 7.2 shows that at least one hole injecting/transporting layer (HIL/HTL) 704 is deposited on top of the anode layer 703.

FIG. 7.3 shows that a CHTEL A 705 containing QDs of type A and a crosslinkable HTM is deposited on top of the HIL/HTL 704. This layer can be crosslinked (i.e., polymerized) when exposed to UV light of specific energy.

FIG. 7.4 shows the UV crosslinkable CHTEL A 705 being exposed to UV light 707 only in correspondence of a specific area of the substrate (i.e., area A), delimitated by the use of a shadow mask 708. A crosslinked CHTEL A 705 is obtained in the area A, this area is now resistant to rinsing with a specific solvent or developer.

FIG. 7.5. shows the substrate 702 with the deposited layers (703, 704) being rinsed with a solvent or developer 709 that washes away the CHTEL A 705 that is not in the area A.

FIG. 7.6 shows that in the area A all layers deposited are present (including CHTEL A 705), while in the areas B and C, only the anode layer 703 and the HIL/HTL 704 layer are present.

FIG. 7.7 shows that a CHTEL B 710 containing QDs of type B and a crosslinkable HTM is deposited on top of the anode layer 703, HIL/HTL 704, and CHTEL A 705 in area A, and on top of the anode layer 703 and HIL/HTL 704 in areas B and C. This layer can be crosslinked (polymerized) when exposed to UV light of specific energy.

FIG. 7.8. shows the UV crosslinkable CHTEL B 710 exposed to UV light 707 only in correspondence of a specific area of the substrate (i.e., area B), delimitated by the use of a shadow mask 708. A crosslinked CHTEL B 710 is therefore obtained in the area B, and this area is now resistant to rinsing with a specific solvent or developer.

FIG. 7.9 shows the substrate 702 with the deposited layers (703, 704, 705, 710) being rinsed with a solvent or developer 709 that washes away the CHTEL B 710 that is not in the area B.

FIG. 7.10 shows that in the area B are present all layers deposited in FIGS. 7.7 (703, 704 and 710), while in the area A are present only the layers deposited up to FIGS. 7.6 (703, 704 and 705) and in the area C are present only the anode 703 and the hole injecting/transporting layers 704.

FIG. 7.11 shows a CHTEL C 711 containing QDs of type C and a crosslinkable HTM deposited on top of the structure represented in FIG. 7.10. In the area A, underneath the CHTEL C 711 are present the CHTEL A 705, the HIL/HTL 704 and the anode 703. In the area B, underneath the CHTEL C 711 are present the CHTEL B 710, the HIL/HTL 704 and the anode 703. In the area C underneath the CHTEL C 711 are present only the HIL/HTL 704 and the anode 703. CHTEL C 711 can be crosslinked (i.e., polymerized) when exposed to UV light of specific energy.

FIG. 7.12 shows the UV crosslinkable CHTEL C 711 exposed to UV light 707 only in correspondence of a specific area of the substrate (i.e., area C), delimitated by the use of a shadow mask 708. A crosslinked CHTEL C 711 is therefore obtained in the area C, and this area is now resistant to rinsing with a specific solvent or developer.

FIG. 7.13 shows the substrate 702 with the deposited layers (703, 704, 705, 710, 711) being rinsed with a solvent or developer 709 that washes away the CHTEL C 711 that is not in the area C.

FIG. 7.14 shows that in the area C are present all layer deposited in FIGS. 7.11 (703, 704 and 711), in the area B are present only the layers deposited up to FIGS. 7.7 (703, 704 and 710), while in the area A are present only the layers deposited up to FIGS. 7.6 (703, 704 and 705).

FIG. 7.15 shows that an interlayer 712 formed by a material with properties as the ones described in implementations of this disclosure, is deposited over CHTEL A 705, CHTEL B 710, and CHTEL C 711, in areas A, B, and C, respectively.

FIG. 7.16 shows that the interlayer 712 is exposed to UV light 707 in order to promote crosslinking. This step is an option and applies only to interlayers 712 composed by a crosslinkable material. Optionally the interlayer 712 can be rinsed with a solvent or developer that washes away portion of the interlayer that are not completely crosslinked in order to improve morphology of the layer.

FIG. 7.17 shows that an electron transporting layer (ETL) 713 is deposited over the interlayer 712, in areas A, B, and C, respectively.

FIG. 7.18 shows a cathode 714 has been deposited over the ETL 713, in areas A, B, and C, including the bank structures 701, to create three QLED sub-pixels in three different areas (A, B, and C), which may be the colors required for a multi-color display. The thickness of the layers deposited may range from 0.1 nm to 150 nm.

RGB Patterned QLEDs with Patternable Interlayer—Approach 1

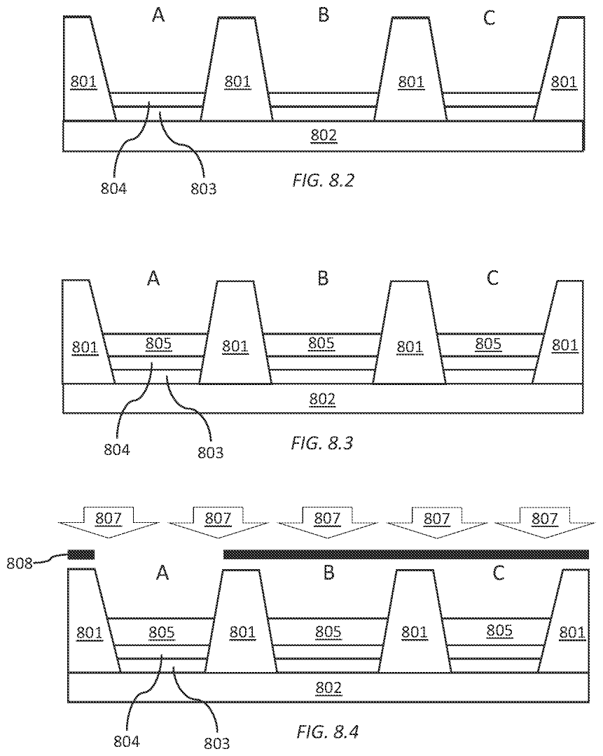

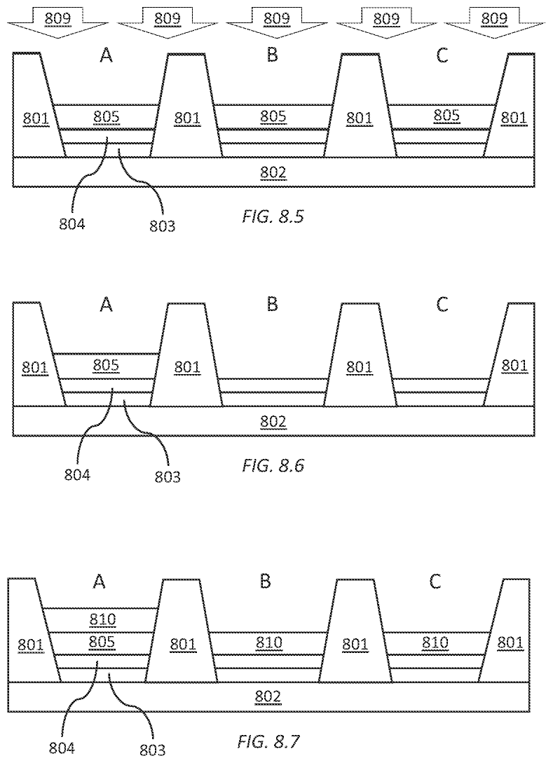

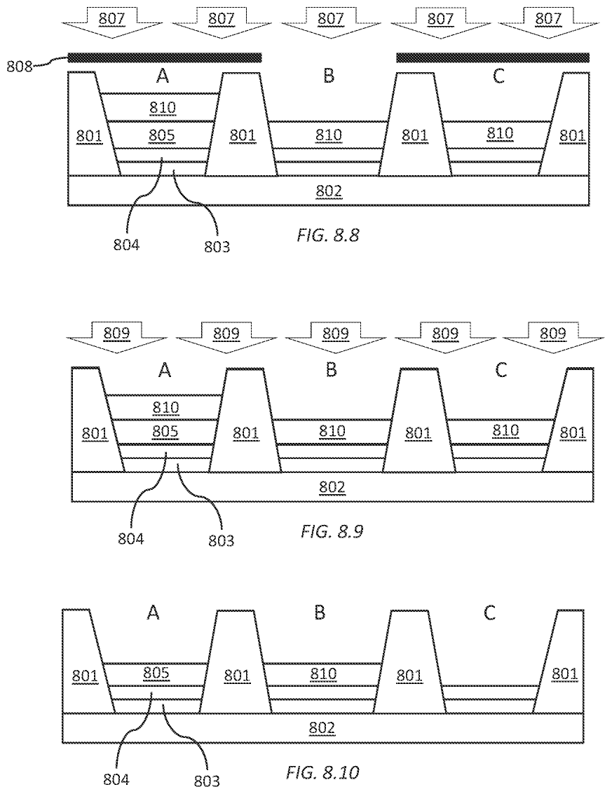

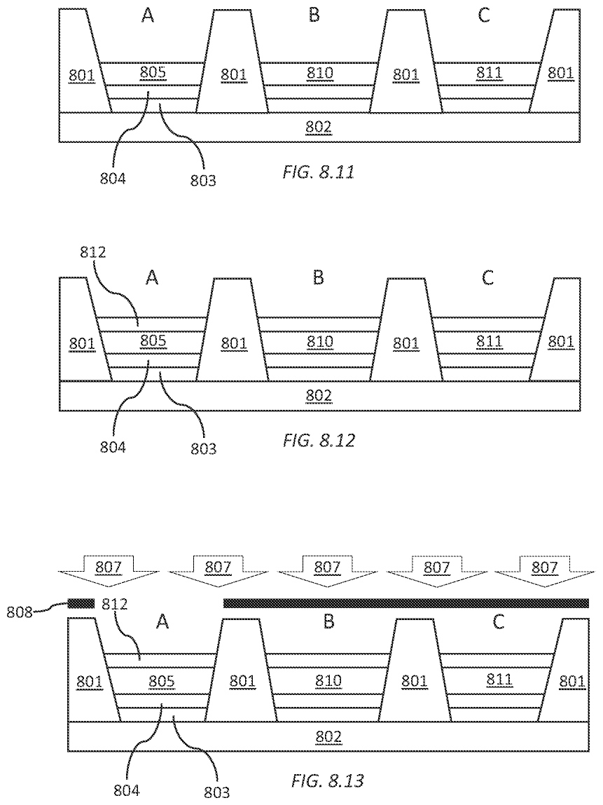

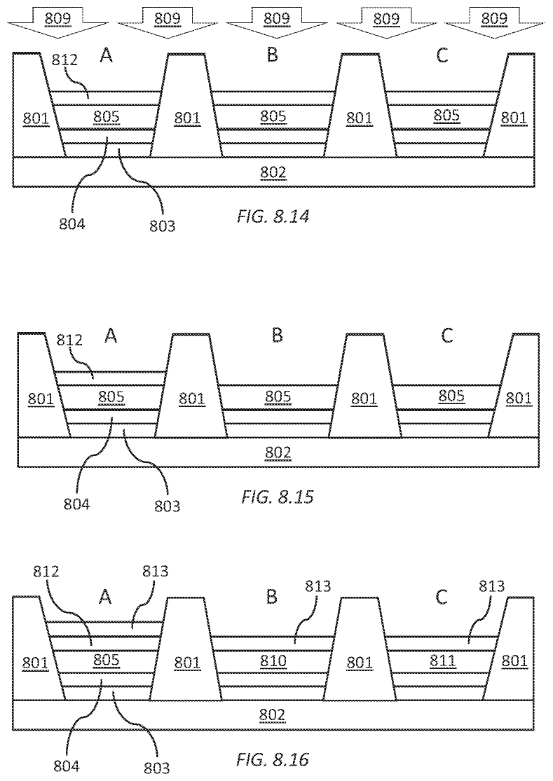

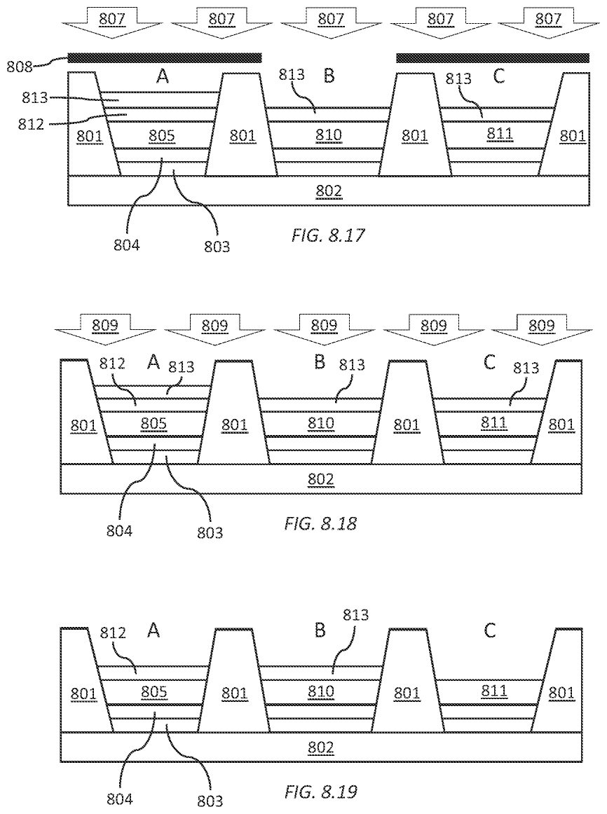

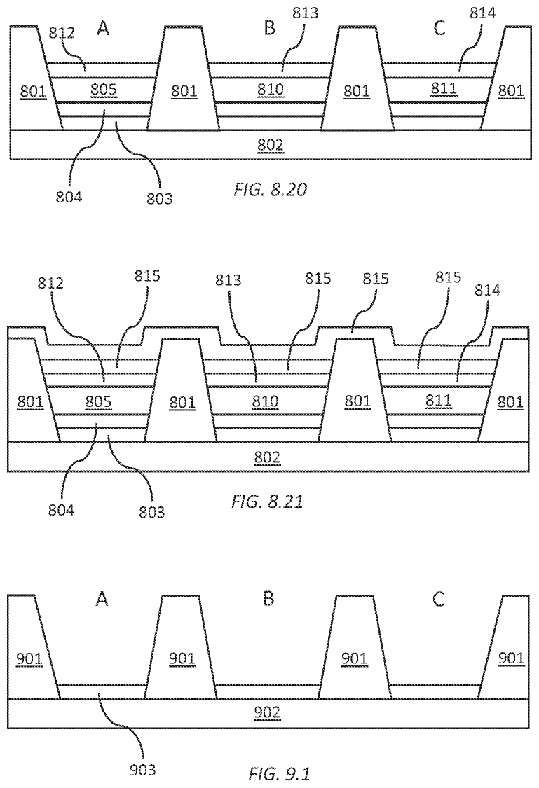

Referring to FIGS. 8.1-8.20, various manufacturing actions are shown in creating RGB patterned QLEDs with a shared interlayer. The method (not to scale) uses the above disclosed structures in order to form three different QLEDs with standard structure on three different regions of a substrate. The three different areas may be sub-pixels that respectively emit light of three different colors and that may collectively form a pixel, which in turn may be a part of an array of pixels of the display. These three structures have a different patternable interlayer structure on top of each structure. The three interlayers can have different thicknesses in the different sub-pixels and they can be formed by different materials, one for each subpixel or the combination of these variations. In this implementation, the three interlayers A, B and C are deposited only when all three different CHTELs are already deposited.

Light-emitting apparatuses may be arranged such that the light-emitting apparatuses are separated at least in part by one or more insulating materials. This arrangement may also be referred to as a “bank structure.” FIGS. 8.1-8.20 are drawings illustrating a cross-section view of such a bank structure 901 that can allocate multiple light-emitting apparatuses formed in accordance with implementations of the present application. In a specific implementation these areas are three and they are labeled A, B and C in order to distinguish three different sub-pixels. They are formed in these areas by taking, at least the following actions:

FIG. 8.1 shows that an anode layer 803 is deposited on top of a substrate 802 with banks 801 shaped in order to accommodate three different sub-pixels (i.e., A, B, and C). The anode layer 803 can be the same in the three areas or different for each area.

FIG. 8.2 shows that at least one hole injecting/transporting layer (HIL/HTL) 804 is deposited on top of the anode layer 803.

FIG. 8.3 shows that a CHTEL A 805 containing QDs of type A and a crosslinkable HTM is deposited on top of the HIL/HTL 804. This layer can be crosslinked (i.e., polymerized) when exposed to UV light of specific energy.

FIG. 8.4 shows the UV crosslinkable CHTEL A 805 being exposed to UV light 807 only in correspondence of a specific area of the substrate (i.e., area A), delimitated by the use of a shadow mask 808. A crosslinked CHTEL A 805 is obtained in the area A, this area is now resistant to rinsing with a specific solvent or developer.

FIG. 8.5. shows the substrate 802 with the deposited layers (803, 804) being rinsed with a solvent or developer 809 that washes away the CHTEL A 805 that is not in the area A.

FIG. 8.6 shows that in the area A all layers deposited are present (including CHTEL A 805), while in the areas B and C, only the anode layer 803 and the HIL/HTL 804 layer are present.

FIG. 8.7 shows that a CHTEL B 810 containing QDs of type B and a crosslinkable HTM is deposited on top of the anode layer 803, HIL/HTL 804, and CHTEL A 805 in area A, and on top of the anode layer 803 and HIL/HTL 804 in areas B and C. This layer can be crosslinked (polymerized) when exposed to UV light of specific energy.

FIG. 8.8. shows the UV crosslinkable CHTEL B 810 exposed to UV light 807 only in correspondence of a specific area of the substrate (i.e., area B), delimitated by the use of a shadow mask 808. A crosslinked CHTEL B 810 is therefore obtained in the area B, and this area is now resistant to rinsing with a specific solvent or developer.

FIG. 8.9 shows the substrate 802 with the deposited layers (803, 804, 805, 810) being rinsed with a solvent or developer 809 that washes away the CHTEL B 810 that is not in the area B.

FIG. 8.10 shows that in the area B are present all layers deposited in FIGS. 8.7 (803, 804 and 810), while in the area A are present only the layers deposited up to FIGS. 8.6 (803, 804 and 805) and in the area C are present only the anode 803 and the hole injecting/transporting layers 804.

FIG. 8.11 shows, in a similar manner as described in the previous FIGS. 8.7-8.10, a CHTEL C 811 containing QDs of type C and a crosslinkable HTM is deposited in area C. This layer can be crosslinked (polymerized) when exposed to UV light of specific energy. The UV crosslinkable CHTEL C 811 is exposed to UV light 807 (FIGS. 8.4 and 8.8) only in correspondence of a specific area of the substrate (area C in this specific implementation), delimitated by the use of a shadow mask 808 (FIGS. 8.4 and 8.8). A crosslinked CHTEL C is obtained in the area C, this area is now resistant to rinsing with a specific solvent or developer. The substrate 802 with the deposited layers is rinsed with a solvent or developer 809 (FIGS. 8.5 and 8.9) that washes away the CHTEL C 811 that is not in the area C. The result is that in the area C are present all layers deposited as represented in FIG. 8.11, while in the area A are present only the layer deposited up to FIG. 8.6 and in the area B are present only the layers deposited up to FIG. 8.10.

FIG. 8.12 shows an interlayer A 812, formed by a material with properties as the ones described in various implementations of this disclosure, is deposited in areas A, B, and C.

FIG. 8.13 shows the interlayer A 812 is exposed to UV light 807 only in correspondence of a specific area of the substrate (area A in this specific implementation), delimitated by the use of a shadow mask 808. A crosslinked interlayer A is obtained in the area A, this area is now resistant to rinsing with a specific solvent or developer.

FIG. 8.14 shows the substrate 802 with the deposited layers is rinsed with a solvent or developer 809 that washes away the interlayer A 812 that is not in the area A.

FIG. 8.15 shows the result, that in the area A are present all layers deposited, including interlayer A 812, while in the areas B and C are present only the layers deposited up to FIG. 8.11.

FIG. 8.16 shows an interlayer B 813, formed by a material with properties as the ones described in implementations of this disclosure, is then deposited in areas A, B, and C.

FIG. 8.17 shows interlayer B 813 is exposed to UV light 807 only in correspondence of a specific area of the substrate 802 (area B in this specific implementation), delimitated by the use of a shadow mask 808. A crosslinked interlayer B is obtained in the area B, this area is now resistant to rinsing with a specific solvent or developer.

FIG. 8.18 shows the substrate 802 with the deposited layers is rinsed with a solvent or developer 809 that washes away the interlayer B 813 that is not in the area B.

FIG. 8.19 shows the result, that in the area B are present all layers deposited in FIG. 8.15, while in the area A are present only the layer deposited up to FIG. 8.12 and in the area C are present only the anode layer 803, the hole injecting/transporting layers 804, and the CHTEL C 811.

FIG. 8.20 shows in a similar way of what was described in the previous FIGS. 8.15-8.18, an interlayer C 814, formed by a material with properties as the ones described in implementations of this disclosure, is deposited. The interlayer C 814 is exposed to UV light 807 only in correspondence of a specific area of the substrate (area C in this specific implementation), delimitated by the use of a shadow mask 808 (in a manner similar to FIGS. 8.13 and 8.16). A crosslinked interlayer C is obtained in the area C, this area is now resistant to rinsing with a specific solvent or developer. The substrate with the deposited layers is rinsed with a solvent or developer 809 that washes away the interlayer C 814 that is not in the area C. The result is that in the area C are present all layers deposited in FIG. 8.19, while in the area A are present only the layer deposited up to FIG. 8.12 and in the area B are present only the layers deposited up to FIG. 8.15.

FIG. 8.21 shows an electron transporting layer 815 is deposited and then a cathode layer 816 is deposited over areas A, B, and C, and the banks 801 to create three QLED subpixels in the three different areas (A, B and C). The thickness of the layers in this implementation may be from 0.1 nm to 150 nm.

RGB Patterned QLEDs with Patternable Interlayer—Approach 2

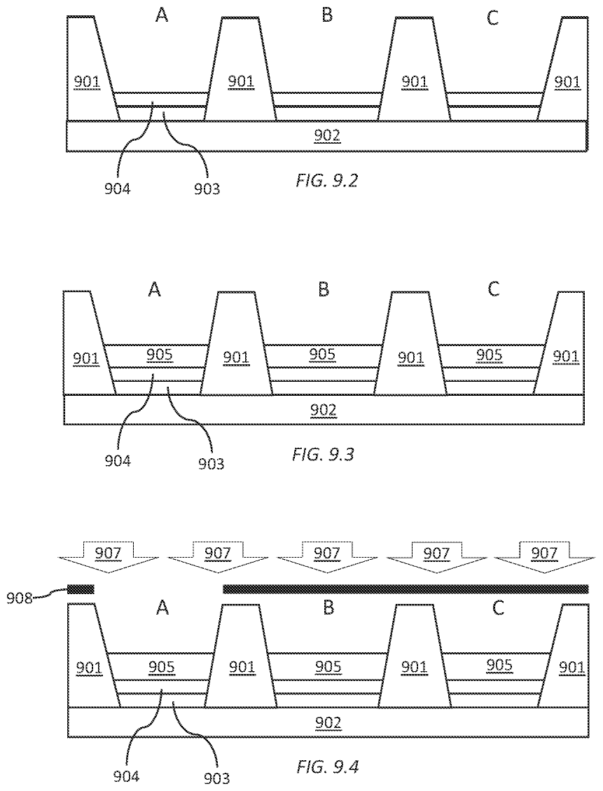

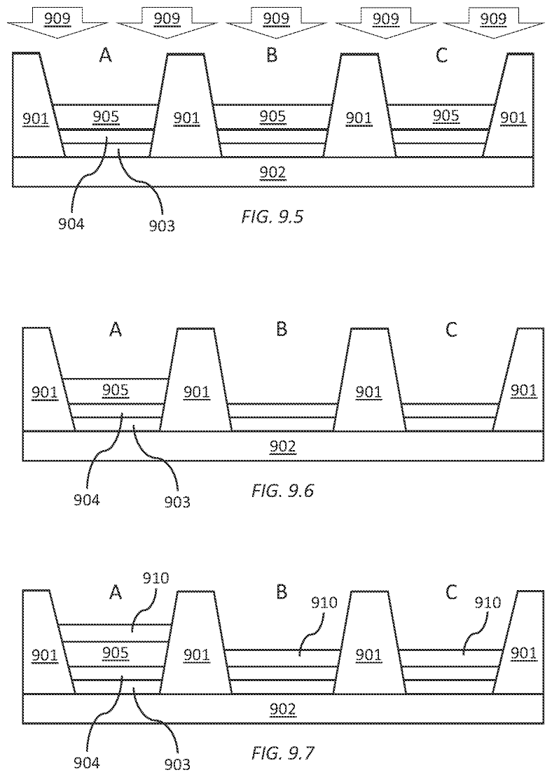

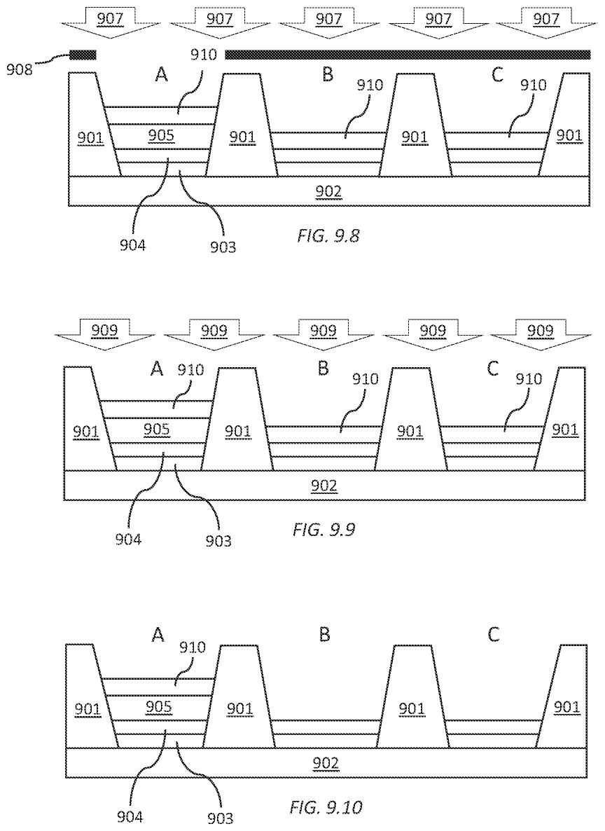

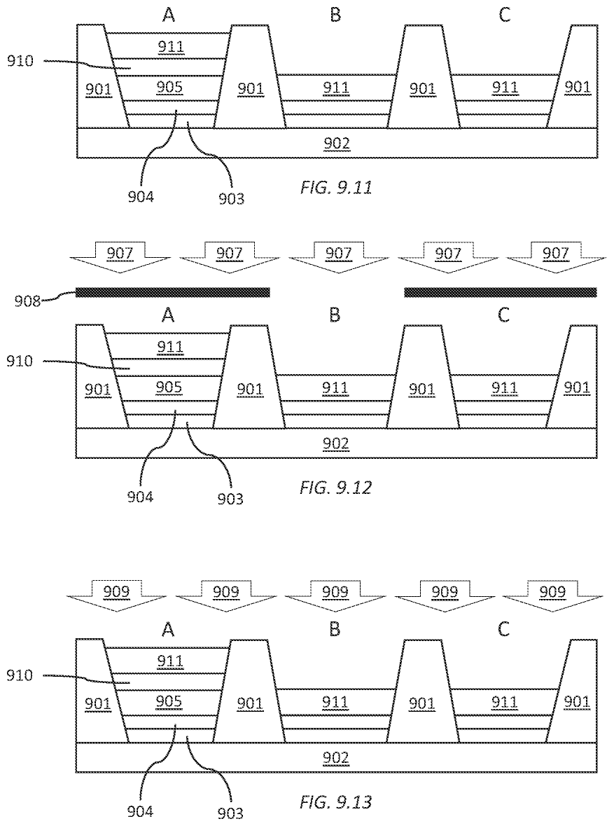

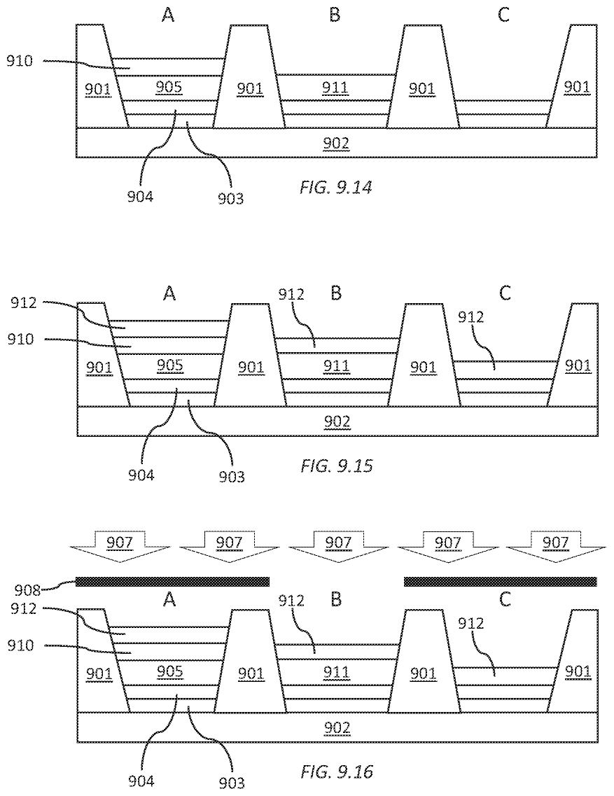

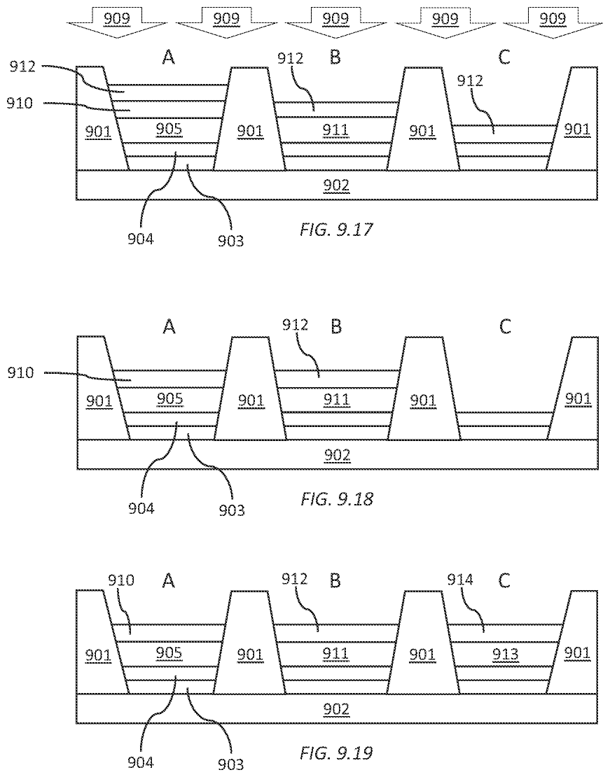

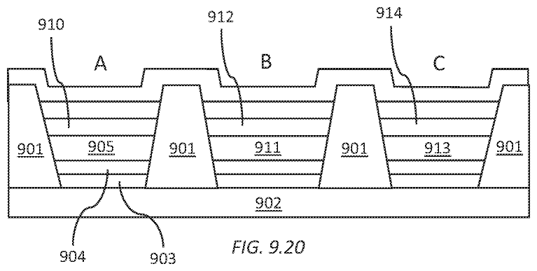

Referring to FIGS. 9.1-9.20, various manufacturing actions are shown in creating RGB patterned QLEDs with a shared interlayer. The method (not to scale) uses the above disclosed structures in order to form three different QLEDs with standard structure on three different regions of a substrate. The three different areas may be sub-pixels that respectively emit light of three different colors and that may collectively form a pixel, which in turn may be a part of an array of pixels of the display. These three QLED sub-pixels each have a different patternable interlayer structure on top of each sub-pixel. The three interlayers can have different thicknesses in the different sub-pixels and they can be formed by different materials, one for each sub-pixel or the combination of these variations. In this implementation, the three interlayers A, B and C are deposited after each corresponding CHTEL A, B and C, respectively. In this implementation, the interlayers play also the role of protecting the respective CHTEL from the process of patterning the remaining layers.

Light-emitting apparatuses may be arranged such that the light-emitting apparatuses are separated at least in part by one or more insulating materials. This arrangement may also be referred to as a “bank structure.” FIGS. 9.1-9.20 are drawings illustrating a cross-section view of such a bank structure 901 that can allocate multiple light-emitting apparatuses formed in accordance with implementations of the present application. In a specific implementation these areas are three and they are labeled A, B and C in order to distinguish three different sub-pixels. They are formed in these areas by taking, at least the following actions:

FIG. 9.1 shows that an anode layer 903 is deposited on top of a substrate 902 with bank structures 901 shaped in order to accommodate three different sub-pixels (i.e., A, B, and C). The anode layer 903 can be the same in the three areas or different for each area.

FIG. 9.2 shows that at least one hole injecting/transporting layer (HIL/HTL) 904 is deposited on top of the anode layer 903.

FIG. 9.3 shows that a CHTEL A 905 containing QDs of type A and a crosslinkable HTM is deposited on top of the HIL/HTL 904. This layer can be crosslinked (i.e., polymerized) when exposed to UV light of specific energy.

FIG. 9.4 shows that the UV crosslinkable CHTEL A 905 is exposed to UV light 907 only in correspondence of a specific area of the substrate (area A in this specific implementation), delimitated by the use of a shadow mask 908. A crosslinked CHTEL A 905 is obtained in the area A, this area is now resistant to rinsing with a specific solvent or developer.

FIG. 9.5 shows that the substrate 902 with the deposited layers is rinsed with a solvent or developer 909 that washes away the CHTEL A 905 that is not in the area A.

FIG. 9.6 shows the result, that in the area A are present all layers deposited, while in the areas B and C, only the anode layer 903 and the HIL/HTL 904 are present.

FIG. 9.7 shows an interlayer A 910, formed by a material with properties as the ones described in implementations of this disclosure, is deposited over the CHTEL A 905 in area A, and in areas B and C.

FIG. 9.8 shows the interlayer A 910 is exposed to UV light 907 only in correspondence of a specific area of the substrate (area A in this specific implementation), delimitated by the use of a shadow mask 908. A crosslinked interlayer A 910 is obtained in the area A, this area is now resistant to rinsing with a specific solvent or developer.

FIG. 9.9 shows the substrate 902 with the deposited layers is rinsed with a solvent or developer 909 that washes away the interlayer A 910 that is not in the area A.

FIG. 9.10 shows the result, that in the area A are present all layers deposited, while in the areas B and C are present only the layers deposited up to FIG. 9.2.

FIG. 9.11 shows a CHTEL B 911 containing QDs of type B 911 and a crosslinkable HTM is deposited. This layer can be crosslinked (polymerized) when exposed to UV light of specific energy.

FIG. 9.12 shows the UV crosslinkable CHTEL B 911 is exposed to UV light 907 only in correspondence of a specific area of the substrate 902 (area B in this specific implementation), delimitated by the use of a shadow mask 908. A crosslinked CHTEL B 911 is obtained in the area B, this area is now resistant to rinsing with a specific solvent or developer.

FIG. 9.13 shows the substrate 902 with the deposited layers is rinsed with a solvent or developer 909 that washes away the CHTEL B 911 that is not in the area B.

FIG. 9.14 shows the result, that in the area B are present all layers deposited in FIG. 9.11, while in the area A are present only the layer deposited up to FIG. 9.10 and in the area C are present only the anode layer 903 and the HIL/HTL 904.

FIG. 9.15 shows an interlayer B 912, formed by a material with properties as the ones described in implementations of this disclosure, is deposited in areas A, B, and C, over the CHTEL A 905 in area A, the CHTEL B 911 in area B, and over the HIL/HTL 904 in area C.

FIG. 9.16 shows the interlayer B 912 is exposed to UV light 907 only in correspondence of a specific area of the substrate 902 (area B in this specific implementation), delimitated using a shadow mask 908. A crosslinked interlayer B is obtained in the area B, this area is now resistant to rinsing with a specific solvent or developer.

FIG. 9.17 shows the substrate 902 with the deposited layers is rinsed with a solvent or developer 909 that washes away the interlayer B 912 that is not in the area B.

FIG. 9.18 shows the result, that in the area B are present all layers deposited in FIG. 9.15, while in the area A are present only the layers deposited up to FIG. 9.14 and in the area C are present only the anode layer 903 and the HIL/HTL 904.

FIG. 9.19 shows that in a similar manner to the processes described in the previous FIGS. 9.11-9.18, a CHTEL C 913 containing QDs of type C and a crosslinkable HTM is deposited. This layer can be crosslinked (polymerized) when exposed to UV light 907 (FIGS. 9.4, 9.8, 9.12, 9.16) of specific energy. The UV crosslinkable CHTEL C 913 is exposed to UV light 907 only in correspondence of a specific area of the substrate (area C in this specific implementation), delimitated by the use of a shadow mask 908 (FIGS. 9.4, 9.8, 9.12, 9.16). A crosslinked CHTEL C 913 is obtained in the area C, this area is now resistant to rinsing with a specific solvent or developer.

The substrate with the deposited layers is rinsed (FIGS. 9.5, 9.9, 9.13, 9.17) with a solvent or developer 909 that washes away the CHTEL C 913 that is not in the area C. The result is similar to what depicted in FIG. 9.18 with the addition of a CHTEL C 913 in the area C. Successively, an interlayer C 914, formed by a material with properties as the ones described in implementations of this disclosure, is deposited. The interlayer C 914 is exposed to UV light 907 (FIGS. 9.4, 9.8, 9.12, 9.16) only in correspondence of a specific area of the substrate (area C in this specific implementation), delimitated by the use of a shadow mask 908 (FIGS. 9.4, 9.8, 9.12, 9.16). A crosslinked interlayer C is obtained in the area C, this area is now resistant to rinsing with a specific solvent or developer. The substrate with the deposited layers is rinsed (FIGS. 9.5, 9.9, 9.13, 9.17) with a solvent or developer 909 that washes away the interlayer C 914 that is not in the area C. The result is depicted in FIG. 9.19, with a common anode layer 903 and HIL/HTL 904, but with specific A, B and C CHTELs (905, 911, 913) and A, B and C interlayers (910, 912, 914) deposited in the three areas A, B and C, respectively.

FIG. 9.20 shows an electron transporting layer 915 is deposited and then a cathode layer 916 is deposited over the layers, and over the bank structures 901, to create three QLED subpixels in the three different areas, A, B and C. The thickness of the layers may be from 0.1 nm to 150 nm.

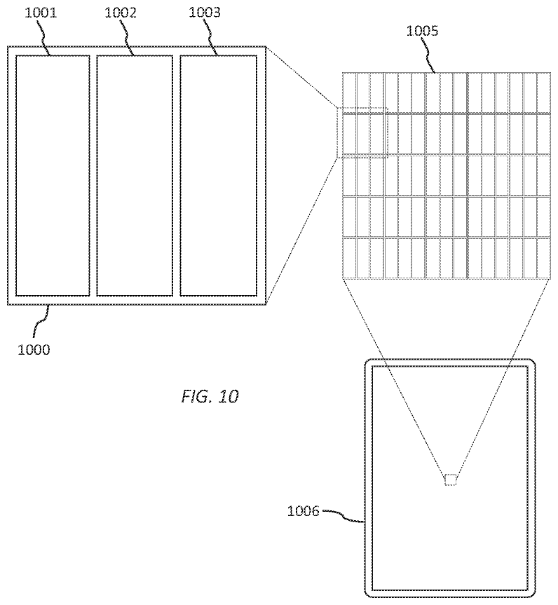

FIG. 10 illustrates a schematic top view of the exemplary implementation of FIGS. 7.1-7.18, FIGS. 8.1-8.20 and FIGS. 9.1-9.20 without the common cathode layer shown. It includes three different QLEDs 1001, 1002 and 1003 with standard structure on three different regions of a substrate. These three areas may be sub-pixels that respectively emit light of three different colors and that may collectively form a pixel 1000, which in turn may be a part of an array of pixels 1005 of a display 1006.

Light-emitting apparatus may be arranged such that the light-emitting apparatus are separated at least in part by one or more insulating materials. This arrangement may also be referred to as a “bank structure.” FIGS. 7.1-7.18, FIGS. 8.1-8.20 and FIGS. 9.1-9.20 are drawings illustrating a cross-section view of the bank structures 701, 801 and 901 that can allocate multiple light-emitting apparatus formed in accordance with implementations of the present application. In a specific implementation these areas are three and they are named A, B and C in order to distinguish three different sub-pixels.

RGB Patterned QLEDs—Variations

Variations of the previous actions described for patterning three sub-pixels:
Interlayers A, B and C can be of different thicknesses;
Interlayers A, B and C can be made with the same or different materials;
Interlayers A, B and C can be crosslinkable or not;
Interlayers A, B and C can be made with one material or of a blend of materials, these can be a mixture of:
   not crosslinkable materials;
   crosslinkable materials;
   some crosslinkable materials and some not;
Interlayers A, B and C can contain or not contain an initiator of the polymerization, and this can be different for each layer;
Layers CHTEL A, CHTEL B and CHTEL C can be of different thicknesses;
The concentration ratio of HTMs contained in the CHTELs can the same or different for each layer;
the HTMs contained in the CHTELs can be different for each layer;
the CHTEL can contain more than one HTMs as disclosed in related art; and
the CHTEL A, CHTEL B and CHTEL C can contain or not contain an initiator of the polymerization, and this can be different for each layer.

Additional Implementations

In some implementations, the solvent used for rinsing is the same solvent used in the deposition of the CHTELs or the interlayers. In other implementations, the solvent used for rinsing is a similar solvent or orthogonal solvent to the solvent used deposition of the CHTELs or the Interlayers.

Accordingly, as shown in FIGS. 7.6, 7.10 and 7.14 the CHTELs (705, 710, 711) remain on the deposition surface. The same happens for the interlayer 712 as shown in FIG. 7.15 (this applies also for analogous implementations depicted in FIGS. 8.1-8.20 and 9.1-9.20). The solvent used in the CHTELs or in the interlayers and the solvent used to wash away the remaining mixture may be evaporated during annealing (e.g., heating) of the deposited layer. The annealing may be performed at any suitable temperature that effectuates evaporation of the solvent while also maintaining the integrity of the quantum dots, electrodes and charge transport materials. In exemplary implementations, annealing may be performed at a temperature ranging from 5° C. to 150° C., or at a temperature ranging from 30° C. to 150° C., or at a temperature ranging from 30° C. to 100° C.

In an exemplary implementation, subsequent to the application of UV light 707 as shown in FIGS. 7.4, 7.8, 7.12 and 7.16 (this applies also for analogous implementations depicted in FIGS. 8.1-8.20 and 9.1-9.20), the layer may be annealed (e.g., heated) to facilitate evaporation and removal of the solvent(s). This annealing may be performed prior to the washing or subsequent to the washing or. In implementations in which the annealing is performed prior to the washing, a subsequent annealing may be performed after washing. As another example, application of UV light 707 as shown in FIGS. 7.4, 7.8, 7.12 and 7.16 and annealing (e.g., heating) may be performed in parallel (this applies also for analogous implementations depicted in FIGS. 8.1-8.20 and 9.1-9.20). This may remove the solvent used in the deposited solution. Subsequent to the rinsing, a subsequent annealing may be performed. As yet another example, annealing may be conducted prior to application of UV light 707 as shown in FIGS. 7.4, 7.8, 7.12 and 7.16, and subsequent to the rinsing, a subsequent annealing may be performed (this applies also for analogous implementations depicted in FIGS. 8.1-8.20 and 9.1-9.20).

Factors such as the UV exposure times, UV-intensity, amount of photo initiator, type and thickness of the deposition surface, surface treatments (as UV-ozone or plasma) and ratio between crosslinkable material and photoinitiator may allow for control of the morphology of the emissive material and of the hole transporting layer. For example, UV exposure time may range from 0.001 seconds to 15 minutes, and/or UV exposure intensity may range from 0.001 to 100,000 mJ/cm². The amount of photo initiator may range from 0.001 to 15 wt % of the total concentration of the crosslinkable material in solution. The concentration of the ligands of the QDs may range from 0 to 35 wt % of the total weight of the QDs. The thickness of the deposition surface may range from 0.1 to 1000 nm. The deposition surface may be composed of any suitable organic, metalorganic or inorganic materials.

In an exemplary implementation, the UV exposure intensity ranges from 1 to 100 mJ/cm² at a UV exposure time of 0.01 to 200 seconds, the concentration of the crosslinkable materials in the solution may range from 0.5 and 10 wt %, and the photo initiator concentration ranges from 0 and 5 wt % of the concentration of the crosslinkable materials in the solution, and the thickness of the deposition surface ranges from 1 to 1000 nm.

The structure and manufacture of the combined charge transporting and emitting layer with improved morphology and balanced charge transporting properties having been shown and described, its exemplary materials will now be discussed.

Substrates

The substrate 201 (FIG. 2) may be made from any suitable material(s) as are typically used in light-emitting apparatuses, such as glass substrates and polymer substrates. More specific examples of substrate materials include polyimides, polyethenes, polyethylenes, polyesters, polycarbonates, polyethersulfones, polypropylenes, and/or polyether ether ketones. The substrate 201 may be any suitable shape and size. In some implementations, the dimensions of the substrate allow for more than one light-emitting apparatus to be provided thereon. In an example, a major surface of the substrate may provide an area for multiple light-emitting apparatuses to be formed as sub-pixels of a pixel, with each sub-pixel emitting light of a different wavelength such as red, green, and blue. In another example, a major surface of the substrate may provide an area for multiple pixels to be formed thereon, each pixel including a sub-pixel arrangement of multiple light-emitting apparatuses.

Deposition Methods

To deposit multiple layers in a typical QLED structure using solution process methods, solution of different materials in adjacent orthogonal solvents should be deposited. Solution process methods include, but are not limited to, methods of drop casting, spin coating, dip coating, slot die coating, spray coating, and inkjet printing.

Electrodes

The first electrode 202 and second electrode 206 (FIG. 2) may be made from any suitable material(s) as are typically used in light-emitting apparatuses. At least one of the electrodes is a transparent or semi-transparent electrode for light emission, and the other of the electrodes is a reflective electrode to reflect any internal light toward the light-emitting side of the apparatus. In the case of a bottom-emitting apparatus, the first electrode 202 will be transparent or semi-transparent. Typical materials for the transparent or semi-transparent electrode include indium-doped tin oxide (ITO), fluorine doped tin oxide (FTO), indium-doped zinc oxide (IZO), aluminum-doped zinc-oxide (AZO), indium-doped cadmium-oxide, and the like. In the case of a top-emitting apparatus, the first electrode 202 may be made of any suitable reflective metal such as silver or aluminum. In bottom-emitting apparatuses, the second electrode 206 is a reflective electrode. Typical materials used for the reflective electrode include metals such as aluminum or silver (cathodes for a standard structure) and gold, aluminum, silver or platinum (anodes for an inverted structure). Top-emitting structures will use a semi-transparent second electrode 206 such as thin (<20 nm) silver, a metallic bilayer (e.g. 2 nm Aluminum/15 nm Silver) or a magnesium-silver alloy. The electrodes 202, 206 may also be provided in any suitable arrangement. As an example, the electrodes 202, 206 may address a thin-film transistor (TFT) circuit.

QDs and Ligands

Exemplary quantum dot core and shell materials include one or more of: InP, CdSe, CdS, CdSeₓS₁₋ₓ, CdTe, CdₓZn₁₋ₓSe, CdₓZn₁₋ₓSe_{y}S_{1-y}, ZnSe, ZnS, ZnSₓTe₁₋ₓ, ZnSeₓTe₁₋ₓ, perovskites of the form ABX₃, Zn_{w}CuₓIn_{1-(w+x)}S, and carbon, where 0≤w, x, y, z≤1. Exemplary ligands 103 include alkyl, -alkenyl, -alkynyl or aryl (linear, branched or cyclic) thiols with 1 to 30 atoms of carbon; alkyl, -alkenyl, -alkynyl or aryl (linear, branched or cyclic) alcohols with 1 to 30 atoms of carbon; alkyl, -alkenyl, -alkynyl or aryl (linear, branched or cyclic) carboxylic acids with 1 to 30 atoms of carbon; tri-alkyl, -alkenyl, -alkynyl or aryl (linear, branched or cyclic) phosphine oxides with 1 to 60 atoms of carbon; alkyl, -alkenyl, -alkynyl or aryl (linear, branched or cyclic) amines with 1 to 30 atoms of carbon; salts formed from any of the above listed compounds (the anion or the cation are the binding moieties); halogen salts (the anion or the cation are the binding moieties). It will be appreciated that while the present disclosure primarily describes the quantum dots as core-shell quantum dots, in some implementations the quantum dots may not be of the core-shell type or they may be of a core/multiple-shells type having more than one shell. The non-core-shell type quantum dots may be made from one or more of the above-mentioned materials, and the quantum dots in accordance with the present disclosure may not include a core-shell configuration.

Solvents and Developer

The solvent or developer used may be any suitable solvent, mixture or solution. For example, the solvent may be selected such that the quantum dots, the crosslinkable material when not polymerised (and the photo initiator, if included) are soluble therein. Exemplary solvents include, but are not limited to, the following or mixtures including the following: acetone, dichloromethane, chloroform, linear or branched alkyl acetates (e.g. ethyl acetate, n-butyl acetate, 2-butyl acetate), linear or branched alkanes with 3 to 30 atoms of carbon (e.g., pentane, hexane, heptane, octane, nonane, decane, undecane, dodecane), linear or branched alcohols with 1 to 20 atoms of carbon (e.g., butanol, 2-propanol, propanol, ethanol, methanol), linear or branched alkoxy alcohols with 2 to 20 atoms of carbon (e.g., 2-Methoxyethanol, 2-Ethoxyethanol), mono, di and tri halogen substituted benzenes (e.g., chlorobenzene, 1,2-dibromobenzene, 1,3-dibromobenzene, 1,4-dibromobenzene, 1,3,5-tribromobenzene, 1,2,4-tribromobenzene), linear or branched ethers with 2 to 20 atoms of carbon, and/or mono, di and tri alkyl substituted benzenes (e.g., toluene, 1,2-Dimethylbenzene, 1,3-Dimethylbenzene, 1,4-Dimethylbenzene), benzene, dioxane, propylene glycol monomethyl ether acetate (PGMEA), 1-methoxy-2-propanol, water. Exemplary solutions may include any alkaline or acidic material in one or in a mixture of the above-mentioned solvents. The particular solvent or developer that is utilized may depend on the specific quantum dots, crosslinkable material, and photo initiator that are selected.

Banks

Exemplary insulating materials for the banks may include, but are not limited to, polyimides. In some examples, the insulating material may include a surface treatment, such as for example fluorine, to modify the insulating material wetting properties. For example, the insulating material may be made hydrophilic to prevent the deposited material from sticking on the banks and to ensure the subpixel is filled properly. The insulating material thus forms wells and the bottoms may include different electrodes (e.g., anodes) for each subpixel.

Photo-Initiators

In some implementations the crosslinked hole transporting layer is formed using one or more photo-initiators. As such, the layer described in this application may include one or more photo-initiators. A photo initiator is a material that initiates polymerization in response to light stimuli. In some implementations, the photo initiator may generate one or more radicals, ions, acids, and/or species that may initiate such polymerization.

In exemplary implementations the initiator is a photo initiator. Example photo initiators include sulfonium- and iodonium-salts (e.g. triphenylsulfonium triflate, diphenyliodonium triflate, iodonium, [4-(octyloxy)phenyl]phenyl hexafluorophosphate, bis(4-methylphenyl)iodonium hexafluorophosphate, diphenyliodonium hexafluoroarsenate, diphenyliodonium hexafluoroantimonate, etc.), chromophores containing the benzoyl group (benzoin ether derivatives, halogenated ketones, dialkoxyacetophenones, diphenylacetophenones, etc), hydroxy alkyl heterocyclic or conjugated ketones, benzophenone- and thioxanthone-moiety-based cleavable systems (such as benzophenone phenyl sulfides, ketosulfoxides, etc), benzoyl phosphine oxide derivatives, phosphine oxide derivatives, trichloromethyl triazines, biradical-generating ketones, peroxides, diketones, azides and aromatic bis-azides, azo derivatives, disulfide derivatives, disilane derivatives, diselenide and diphenylditelluride derivatives, digermane and distannane derivatives, peresters, Barton's ester derivatives, hydroxamic and thiohydroxamic acids and esters, organoborates, titanocenes, chromium complexes, aluminate complexes, tempo-based alkoxyamines, oxyamines, alkoxyamines, and silyloxyamines.

In some implementations, when the specific area of the deposited layer is exposed to UV light, the photo initiator initiates the polymerization of the crosslinkable material. QDs, ligands of the QDs, crosslinkable material, charge transporting material, and photo-initiator can be selected to create uniform dispersion in the deposition solvent. Materials with similar polarity indexes can be selected to ensure homogeneity of the deposited mixtures.

Electron Transporting/Injecting Materials

In exemplary implementations, the electron transport and/or electron injection layers may include individual or combinations of: ZnO, 8-quinolinolato lithium (Liq.), LiF, Cs₂CO₃, MgₓZn₁₋ₓO, AlₓZn₁₋ₓO, 2,2′,2″-(1,3,5-benzinetriyl)-tris(1-phenyl-1-H-benzimidazole) (TPBi), TiO2, ZrO2, N4,N4′-Di(naphthalen-1-yl)-N4,N4′-bis(4-vinylphenyl) biphenyl-4,4′-diamine (VNPB), 9,9-Bis[4-[(4-ethenylphenyl)methoxy]phenyl]-N2,N7-di-1-naphthalenyl-N2,N7-diphenyl-9H-Fluorene-2,7-diamine (VB-FNPD), where 0≤x≤1.

Hole Transporting/Injecting Materials

In exemplary implementations, the hole transport and/or hole injection layers may include individual or combinations of: poly(3,4-ethylenedioxythiophene):poly(styrenesulfonate) (PEDOT:PSS), poly(9,9-dioctylfluorene-co-N-(4-sec-butylphenyl)-diphenylamine) (TFB), poly(9-vinylcarbazole) (PVK), poly(N,N′-bis(4-butylphenyl)-N,N′-bisphenylbenzidine) (PolyTPD), V₂O₅, NiO, CuO, WO₃, MoO₃, 2,3,5,6-tetrafluoro-7,7,8,8-tetracyanoquinodimethane (F4TCNQ), 1,4,5,8,9,11-hexaazatriphenylenehexacarbonitrile (HATCN), N4,N4′-Bis(4-(6-((3-ethyloxetan-3-yl)methoxy)hexyl)phenyl)-N4,N4′-diphenylbiphenyl-4,4′-diamine (OTPD), N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD), N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC), 3,5-di-9H-carbazol-9-yl-N,N-bis[4-[[6-[(3-ethyl-3-oxetanyl)methoxy]hexyl]oxy]phenyl]-benzenamine (Oxe-DCDPA).

Crosslinkable Hole Transporting Materials

The crosslinked material is originated from the polymerization of a crosslinkable organic (or organo-metallic) material.

UV-induced crosslinked charge transport materials include UV-induced crosslinked hole transport materials and/or UV-induced crosslinked electron transport materials. Accordingly, the matrix of one or more UV-induced crosslinked charge transport materials may be formed from one or more types of crosslinkable materials. Such materials include one or more hole transport materials and/or one or more electron transport materials. In some implementations, the crosslinkable hole transport material may be a material which is an effective hole transporter both without and with crosslinking. In other implementations, the crosslinkable hole transport material may be a material which is an effective hole transporter only when crosslinked. In some implementations, the crosslinkable electron transport material may be a material which is an effective electron transporter both without and with crosslinking. In other implementations, the crosslinkable electron transport material may be a material which is an effective electron transporter only when crosslinked. In some implementations, the cross-linked charge transport materials can include one or more of hole injection materials, electron injection materials, hole blocking materials, electron blocking materials, and/or interconnecting materials (ICM).

In some implementations, the crosslinkable material from which the UV-induced crosslinked charge transport material may be formed includes at least two moieties with different characteristics. As an example, one of the at least two moieties of the molecule may provide charge transporting properties and another of the at least two moieties of the molecule may provide UV-crosslinking capabilities. Exemplary moieties that may provide charge transporting properties include, but are not limited to, tertiary, secondary, and primary aromatic or aliphatic amines, heterocyclic amines, tryaryl phosphines, and quinolinolates. Exemplary moieties that may provide UV-crosslinking capabilities include, but are not limited to, oxetane, epoxy, thiol, azide, alkane, alkene, alkyne, acrylate, methacrylate, ketone, and aldehyde units. In some implementations, the two moieties may be connected and between them there may be a distance of less than 20 nm.

In some implementations the mixture of the crosslinkable material with the QDs can include a small molecule co-monomer that can allow polymerization. The co-monomer may contain at least one functional group X that may interact with a functional group Y of the crosslinkable material. The crosslinkable material may include such functional group Y at two or more molecular sites. For example, the functional group X may be at two ends of the co-monomer; the functional groups Y may be at two ends of the crosslinkable material. In one implementation, the functional groups X may be a thiol, and the function groups Y may be an alkene or alkyne, or vice versa.

Ligands of the QDs, co-monomers and crosslinkable materials included in the mixture can be selected to create uniform dispersion in the deposition solvent. Materials with similar polarity indexes can be selected to ensure homogeneity of the deposited mixtures.

One example of a crosslinkable material from which the structure described above may be formed is N4,N4′-Bis(4-(6-((3-ethyloxetan-3-yl)methoxy)hexyl)phenyl)-N4,N4′-diphenylbiphenyl-4,4′-diamine (OTPD), as shown in FIG. 11.

Another example of a crosslinkable material from which the structure described above may be formed is N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD), as shown in FIG. 12.

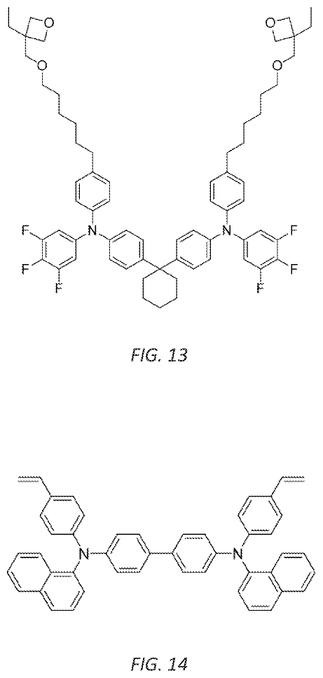

Another example of a crosslinkable material from which the structure described above may be formed is N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC), as shown in FIG. 13.

Another example of a crosslinkable material from which the structure described above may be formed is N4,N4′-Di(naphthalen-1-yl)-N4,N4′-bis(4-vinylphenyl)biphenyl-4,4′-diamine (VNPB), as shown in FIG. 14.

Another example of a crosslinkable material from which the structure described above may be formed is 9,9-Bis[4-[(4-ethenylphenyl)methoxy]phenyl]-N2,N7-di-1-naphthalenyl-N2,N7-diphenyl-9H-Fluorene-2,7-diamine (VB-FNPD), as shown in FIG. 15.

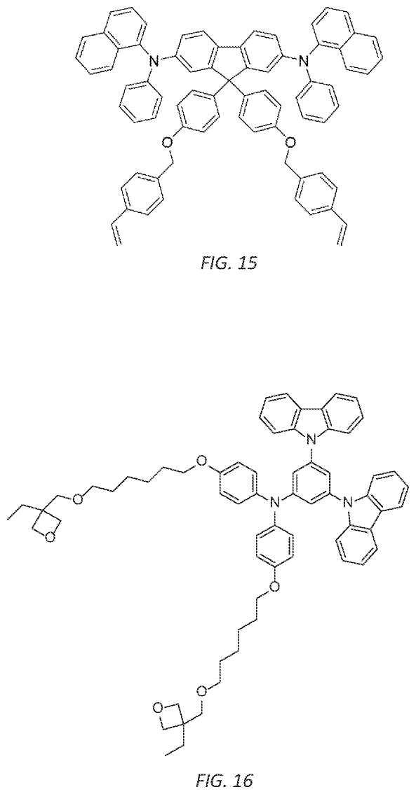

Another example of a crosslinkable material from which the structure described above may be formed is 3,5-di-9H-carbazol-9-yl-N,N-bis[4-[[6-[(3-ethyl-3-oxetanyl)methoxy]hexyl]oxy]phenyl]-benzenamine (Oxe-DCDPA), as shown in FIG. 16.

Interlayer

The interlayer material can be any of the materials described in the “Crosslinkable hole transporting materials”, “Hole transporting materials”, “Electron Injecting materials”, “Hole injecting materials” and “Electron transporting material” sections. In addition, also insulating materials can be used in specific implementations of this disclosure. An insulating material is intended to have an energy band gap superior of 9 eV. Exemplary insulating materials are: Poly(methyl methacrylate) (PMMA), Poly(methyl acrylate) (PMA), Polycarbonates (PC), etc.

Spacers

A spacer or crosslinkable spacer is a material constituted by at least three moieties. The first two are constituted by a functional group with crosslinkable capacities and the third one is an organic backbone that links two or more crosslinkable groups. Optionally the organic backbone can have charge transporting capabilities. Exemplary moieties that may provide charge transporting properties include, but are not limited to, tertiary, secondary, and primary aromatic or aliphatic amines, tryaryl phosphines, and quinolinolates. Exemplary moieties that may provide crosslinking capabilities include, but are not limited to, oxetane, epoxy, thiol, alkene, alkyne, ketone, and aldehyde units. In some implementations, between the two moieties that provide crosslinking capabilities there may be a distance of less than 20 nm.

Exemplary crosslinkable spacers include, but are not limited to, 1,4-Pentadiene; 1,5-Hexadiene; 1,7-heptadiene; 1,7-Octadiene; 1,8-Nonadiene; 1,9-Decadiene; 2-Methyl-1,5-hexadiene; 1,4-Pentadiene; 1,6-Heptadiyne; 1,7-Octadiyne; Propargyl ether; 1,8-Nonadiyne; 1,4-Diethynylbenzene; Dipropargylamine; 4,7,10,13,16-Pentaoxanonadeca-1,18-diyne; 1,3-Diethynylbenzene; 1,4-Diethynylbenzene; 1,3,5-Triethynylbenzene, etc.

Crosslinkable Ligands

A crosslinkable ligand of QD is a material constituted by at least three moieties. The first one is constituted by at least one functional group with crosslinkable capacities, the second one is constituted by at least one functional group that provides linkage to the QD and the third one is an organic backbone that links the at least one functional group with crosslinkable capacities to the at least one functional group that provides linkage to the QD. Optionally the organic backbone can have charge transporting capabilities. Exemplary moieties that may provide charge transporting properties include, but are not limited to, tertiary, secondary, and primary aromatic or aliphatic amines, tryaryl phosphines, and quinolinolates. Exemplary moieties that may provide crosslinking capabilities include, but are not limited to, oxetane, epoxy, thiol, alkene, alkyne, ketone, acrylate, methacrylate, and aldehyde units. Exemplary moieties that may provide linkage to the QD include, but are not limited to, thiol, amine, phosphine, carboxylic acid. In some implementations, between the two moieties that provide crosslinking capabilities there may be a distance of less than 20 nm.

Exemplary crosslinkable ligands include, but are not limited to, benzene-1,4-dithiol, pentaerythritol tetrakis(3-mercaptopropionate) (PETMP); trimethylolpropane tris(3-mercaptopropionate) (TMPMP); 2,2′-(ethylenedioxy)diethanethiol; Tris[2-(3-mercaptopropionyloxy)ethyl]isocyanurate (TEMPIC); 1,3,5-Tris(2-hydroxyethyl)isocyanurate; tris(2,3-epoxypropyl) isocyanurate; trithiocyanuric acid; 1,3,5-tris(2-hydroxyethyl)isocyanurate; glycol Di(3-mercaptopropionate) (GDMP); Di-Pentaerythritol Hexa(3-mercaptopropionate) (DiPETMP); ethoxylated trimethylolpropane tri (3-mercaptopropionate); ethoxylated trimethylolpropane tri (3-mercaptopropionate); polycaprolactone tetra(3-mercaptopropionate); pentaerythritol tetraacrylate, 6-mercaptohexanoic acid; 4-mercaptobutyric acid; 2-mercaptopropionic acid; pentaerythritol tetraacrylate; 11-mercaptoundecanoic acid; mercaptosuccinic acid; and the like.

Optical Cavity

It is known that for top-emitting apparatuses that include reflective electrodes (e.g. the first electrodes) and partially reflective electrodes (e.g. the second electrode), an optical cavity can be established for the light emitted from QDs by electroluminescence. The distance between the QDs emitting light and the first electrode, and the distance between the QDs emitting light and the second electrode, can have a significant effect on the optical mode of the cavity, and consequently on the properties of the light emitted through the second electrode. For example, such parameters can affect the efficiency of light escaping from the light emitting apparatus, and the dependence of intensity and wavelength on emission direction. Therefore, it is often preferable to select the thickness of layers disposed between the QDs and the electrodes to provide a favorable optical cavity for optimal light efficiency. Suitable thicknesses are different for different wavelengths of light (e.g. different between an apparatus emitting red light and an apparatus emitting green light).

What is claimed is:

1. A light-emitting apparatus, comprising:
an anode;
a cathode;
a combined charge transport and emissive layer disposed between the anode and the cathode; and
an interlayer of a material with at least electron blocking properties, the interlayer disposed adjacent an upper outer surface of the combined charge transport and emissive layer, wherein:
the combined charge transport and emissive layer comprises quantum dots (QDs) with ligands; and
the QDs are dispersed in a crosslinked matrix formed at least partially from at least one crosslinkable charge transport material other than the ligands.

2. The light-emitting apparatus of claim 1, wherein the interlayer is formed by a crosslinked, crosslinkable material with one or more functional groups.

3. The light-emitting apparatus of claim 2, wherein the one or more functional groups comprise an epoxide, an oxetane, an alkane, an alkene, an alkyne, a thiol, an aldehyde, a ketone, an acrylate, a methacrylate, a carboxyl, or an azide.

4. The light-emitting apparatus of claim 1, wherein the ligands of the QDs comprise one or more second functional groups.

5. The light-emitting apparatus of claim 4, wherein the one or more second functional groups comprise an epoxide, an oxetane, an alkane, an alkene, an alkyne, a thiol, an aldehyde, a ketone, an acrylate, a methacrylate, a carboxyl, or an azide.

6. The light-emitting apparatus of claim 1, wherein at least one of the interlayer and the combined charge transport and emissive layer further includes a crosslinkable spacer material with one or more functional groups.

7. The light-emitting apparatus of claim 6, wherein the one or more functional groups comprise an epoxide, an oxetane, an alkane, an alkene, an alkyne, a thiol, an aldehyde, a ketone, an acrylate, a methacrylate, a carboxyl, or an azide.

8. The light-emitting apparatus of claim 1, wherein the interlayer is crosslinked to the combined charge transport and emissive layer through the crosslinked matrix formed at least partially from the at least one crosslinkable charge transport material other than the ligands.

9. The light-emitting apparatus of claim 1, wherein the interlayer is crosslinked to the combined charge transport and emissive layer through the ligands of the QDs.

10. The light-emitting apparatus of claim 6, wherein the interlayer is crosslinked to the combined charge transport and emissive layer through the crosslinked matrix formed at least partially from the at least one crosslinkable charge transport material other than the ligands by a crosslinkable spacer material.

11. The light-emitting apparatus of claim 6, wherein the interlayer is crosslinked to the combined charge transport and emissive layer through the ligands of the QDs by a crosslinkable spacer material.

12. The light emitting apparatus of claim 1, wherein at least one of the combined charge transport and emissive layer and the interlayer further comprises one or more initiators.

13. The light emitting apparatus of claim 1, wherein at least one of the combined charge transport and emissive layer and the interlayer further comprises one or more photoinitiators.

14. The light-emitting apparatus of claim 1, wherein the at least one crosslinkable charge transport material comprises one or more hole transport materials.

15. The light-emitting apparatus of claim 1, further comprising a hole injection layer disposed between the anode and the hole transport layer.

16. The light-emitting apparatus of claim 15, further comprising a hole transport layer disposed between the anode and the combined charge transport and emissive layer.

17. The light-emitting apparatus of claim 1, further comprising an electron transport layer disposed between the cathode and the combined charge transport and emissive layer, and wherein at least one crosslinkable charge transport material comprises at least one of a tertiary, secondary, or primary aromatic amine.

18. A light emitting structure, comprising:
a substrate; and
a plurality of sub-pixel structures over the substrate, wherein:
at least one of the plurality of sub-pixel structures includes:
an anode;
a cathode;
a combined charge transport and emissive layer disposed between the anode and the cathode; and
an interlayer of a material that has at least electron blocking properties disposed adjacent an upper outer surface of the combined charge transport and emissive layer;
the combined charge transport and emissive layer comprises quantum dots (QDs) with ligands;
the QDs are dispersed in a crosslinked matrix formed at least partially from at least one crosslinkable charge transport material other than the ligands;
the interlayer is formed by a crosslinked, crosslinkable material having one or more first functional groups; and
the one or more first functional groups comprise an epoxide, an oxetane, an alkane, an alkene, an alkyne, a thiol, an aldehyde, a ketone, an acrylate, a methacrylate, a carboxyl, or an azide.

19. The light emitting structure of claim 18, wherein:
ligands of the QDs have one or more second functional groups; and
the one or more second functional groups comprise an epoxide, an oxetane, an alkane, an alkene, an alkyne, a thiol, an aldehyde, a ketone, an acrylate, a methacrylate, a carboxyl, or an azide.

20. The light emitting structure of claim 18, wherein at least one of the plurality of sub-pixel structures further comprises:
one or more electron injecting or transporting layers between the cathode and the combined charge transport and emissive layer; and
one or more hole injecting or transporting layers between the anode and the combined charge transport and emissive layer.
